(19) United States
(12) Patent Application Publication
(10) Pub. No.: US 2015/0227248 A1
(43) Pub. Date: Aug. 13, 2015

(54) DISPLAY PANEL AND DATA PROCESSING DEVICE

(71) Applicant: Semiconductor Energy Laboratory Co., Ltd., Atsugi-shi (JP)

(72) Inventors: Shunpei YAMAZAKI, Tokyo (JP); Yuji IWAKI, Isehara (JP)

(21) Appl. No.: 14/616,849

(22) Filed: Feb. 9, 2015

(30) Foreign Application Priority Data
Feb. 13, 2014 (JP) 2014-024974

(51) Int. Cl. G06F 3/041; H05K 7/02

(52) U.S. Cl. CPC G06F 3/0412; H05K 7/02; G06F 2203/04102

(57) ABSTRACT

A novel display panel that is highly convenient or reliable is provided. A novel data processing device that is highly convenient or reliable is provided. A novel human interface that is highly convenient or reliable is provided. A structure including a display region where a first region, a first bendable region, and a second bendable region are arranged in stripes is devised. The display region can be folded along a fold line formed in the first bendable region such that the ratio of the length of the short side of the first region to the length of the long side thereof is 0.9 times or more and 1.1 times or less the ratio of the length of the short side of the display region to the length of the long side thereof.

### TECHNICAL FIELD

One embodiment of the present invention relates to a method and a program for processing and displaying image data, and a device including a storage medium in which the program is stored. Specifically, one embodiment of the present invention relates to a method for processing and displaying image data by which an image containing data processed by a data processing device provided with a display portion is displayed, a program for displaying an image containing data processed by a data processing device provided with a display portion, and a data processing device including a recording medium in which the program is recorded.

Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display device, a light-emitting device, a power storage device, a storage device, a driving method thereof, and a manufacturing method thereof.

### BACKGROUND ART

The social infrastructures relating to means for transmitting information have advanced. This has made it possible to acquire, process, and send out many pieces and various kinds of information with the use of a data processing device not only at home or office but also at other visiting places.

With this as a backdrop, portable data processing devices are under active development.

For example, portable data processing devices are often used while being carried around by a user, and force might be accidentally applied, by dropping, to the data processing devices and display devices included in them. As an example of a display device that is not easily broken, a display device having high adhesiveness between a structure body by which a light-emitting layer is divided and a second electrode layer is known (Patent Document 1).

### REFERENCE

[Patent Document 1] Japanese Published Patent Application No. 2012-190794

### DISCLOSURE OF INVENTION

An object of one embodiment of the present invention is to provide a novel display panel that is highly convenient or reliable. Another object of one embodiment of the present invention is to provide a novel data processing device that is highly convenient or reliable. Another object of one embodiment of the present invention is to provide a novel human interface that is highly convenient or reliable. Another object of one embodiment of the present invention is to provide a novel display panel, a novel data processing device, or the like.

Note that the descriptions of these objects do not disturb the existence of other objects. In one embodiment of the present invention, there is no need to achieve all the objects. Other objects will be apparent from and can be derived from the description of the specification, the drawings, the claims, and the like.

One embodiment of the present invention is a display panel including a display region where a first region, a first bendable region, and a second region are arranged in stripes in this order. The display region can be folded and unfolded along a fold line formed in the first bendable region.

The ratio of the length of a short side of the first region to the length of a long side thereof is 0.9 times or more and 1.1 times or less the ratio of the length of a short side of the display region to the length of a long side thereof.

One embodiment of the present invention is the display panel in which the ratio of the length of the short side of the first region to the length of the long side thereof is approximately 9:16.

One embodiment of the present invention is a display panel including a display region where a first region, a first bendable region, a second region, a second bendable region, and a third region are arranged in stripes in this order. The display region can be folded and unfolded along a first fold line formed in the first bendable region and a second fold line formed in the second bendable region. The ratio of the length of a short side of the first region to the length of a long side thereof is 0.9 times or more and 1.1 times or less the ratio of the length of a short side of the display region to the length of a long side thereof. The ratio of the length of the short side of the first region to the length of the long side thereof is approximately 9:16.

The display panel of one embodiment of the present invention includes the display region where the first region, the first bendable region, and the second bendable region are arranged in stripes. The display region can be folded along a fold line formed in the first bendable region such that the ratio of the length of the short side of the first region to the length of the long side thereof is 0.9 times or more and 1.1 times or less the ratio of the length of the short side of the display region to the length of the long side thereof.

With such a structure, an image having approximately the same ratio of the vertical length to the horizontal length as an image displayed on the first region of the folded display panel can be displayed on the display region in an unfolded state. Thus, the novel display panel can be highly convenient or reliable.

One embodiment of the present invention is a data processing device including an input/output device and an arithmetic device. The input/output device is supplied with image data and supplies sensing data. The arithmetic device supplies image data and is supplied with sensing data.

The input/output device includes a display portion and a sensor portion. The display portion is supplied with image data. The sensor portion supplies sensing data.

The display portion includes a display region where a first region, a first bendable region, a second region, a second bendable region, and a third region are arranged in stripes in this order. The ratio of the length of a short side of the first region to the length of a long side thereof is 0.9 times or more and 1.1 times or less the ratio of the length of a short side of the display region to the length of a long side thereof. The ratio of the length of the short side of the first region to the length of the long side thereof is approximately 9:16. The display portion can be folded and unfolded along a first fold line formed in the first bendable region and a second fold line formed in the second bendable region.

The sensor portion determines whether the display portion is folded or whether it is unfolded and supplies sensing data that contains data showing the determined state.

The arithmetic device supplies image data containing a first image that fits the first region in the case where the sensing data shows the folded state, and supplies image data containing a second image that is approximately similar to the first image and fits the display region of the display portion in the case where the sensing data shows the unfolded state. The area of the second image is 2.7 times or more and 3.3 times or less that of the first image. Note that in this specification, the first image is approximately similar to the second image when the ratio between components of a second vector connecting a point of the second image that corresponds to one point of the first image and a point of the second image that corresponds to another point of the first image is 0.75 times or more and 1.25 times or less, preferably 0.9 times or more and 1.1 times or less the ratio between components of a first vector connecting one point and another point of the first image.

One embodiment of the present invention is a data processing device including an input/output device and an arithmetic device. The input/output device is supplied with image data and supplies sensing data. The arithmetic device supplies image data and is supplied with sensing data.

The input/output device includes a display portion and a sensor portion. The display portion is supplied with image data. The sensor portion supplies sensing data.

The display portion includes a display region where a first region, a first bendable region, and a second region are arranged in stripes in this order. The display portion can be folded and unfolded along a first fold line formed in the first bendable region. The sensor portion determines whether the display portion is folded or whether it is unfolded and supplies sensing data that contains data showing the determined state.

The arithmetic device supplies image data containing a first image that fits the first region in the case where the sensing data shows the folded state, and supplies image data containing a second image that is approximately similar to the first image and fits the display region in the case where the sensing data shows the unfolded state. The ratio of the vertical length of the second image to the horizontal length thereof is 0.9 times or more and 1.1 times or less the ratio of the vertical length of the first image to the horizontal length thereof.

The above-described data processing device of one embodiment of the present invention includes the input/output device and the arithmetic device. The input/output device includes the display portion and the sensor portion. The display portion is supplied with image data and can be folded. The sensor portion determines whether the display portion is folded or whether it is unfolded and supplies sensing data containing data that shows the determined state. The arithmetic device supplies image data and is supplied with sensing data.

With such a structure, the second image having approximately the same ratio of the vertical length to the horizontal length as the first image that can be displayed so as to fit the first region of the folded display portion can be displayed so as to fit the display region of the unfolded display portion. Thus, the novel data processing device can be highly convenient or reliable.

One embodiment of the present invention is the above-described data processing device in which the second image is larger than the first image.

One embodiment of the present invention is the data processing device in which one of the vertical length and the horizontal length of the first image is 0.9 times or more the length of a short side or a long side of the first region, or one of the vertical length and the horizontal length of the second image is 0.9 times or more the length of a short side or a long side of the display region.

In that case, an image having approximately the same ratio of the vertical length to the horizontal length can be displayed by being downsized or enlarged in accordance with the size of the folded or unfolded display portion. Thus, the novel data processing device can be highly convenient or reliable.

One embodiment of the present invention is the data processing device in which the image data contains a third image displayed outside a region where the first image or the second image is displayed.

With such a structure, the image data containing the third image can be displayed outside the region where the first image or the second image is displayed. Thus, the novel data processing device can be highly convenient or reliable.

One embodiment of the present invention is the data processing device in which the sensor portion determines the position of the display portion and supplies sensing data containing data that shows the determined position, and the arithmetic device determines the direction of the first image or the second image on the basis of the sensing data and generates image data containing the first image or the second image located in the determined direction.

The above-described data processing device of one embodiment of the present invention includes the sensor portion and the arithmetic device. The sensor portion determines the position (e.g., inclination) of the display portion and supplies sensing data containing data that shows the determined position. The arithmetic device generates image data in accordance with the determined position. Thus, an image can be displayed on the display portion in the direction determined in accordance with the position of the display portion. Accordingly, the novel data processing device can be highly convenient or reliable.

One embodiment of the present invention is a data processing device including an arithmetic portion and a storage portion that stores a program to be executed by the arithmetic portion.

The program includes a first step of acquiring initial data containing status data; a second step of allowing interrupt processing; a third step of acquiring predetermined data; a fourth step of selecting a fifth step when the status data shows a first status or a sixth step when the status data shows a second status; the fifth step of generating image data containing a first image such that it fits a first region on the basis of the data acquired in the third step and displaying the image data; the sixth step of generating image data containing a second image such that it fits a display region of a display portion on the basis of the data acquired in the third step and displaying the image data; a seventh step of selecting an eighth step when a termination instruction is supplied in the interrupt processing or the third step when no termination instruction is supplied in the interrupt processing; and the eighth step of terminating the program.

The interrupt processing includes a ninth step of acquiring sensing data containing data that shows the folded or unfolded state of the display portion; a tenth step of determining candidate data on the basis of the sensing data; an eleventh step of selecting a twelfth step when the candidate data differs from the status data or the ninth step when the candidate data is the same as the status data; the twelfth step of updating the status data to the candidate data; and a thirteenth step of returning from the interrupt processing.

In the above-described data processing device of one embodiment of the present invention, the program includes a step of determining candidate data by acquiring the sensing data containing data that shows the folded or unfolded state of the display portion; a step of updating the status data to the candidate data when the status data differs from the candidate data; and a step of generating and displaying image data containing predetermined data on the basis of the updated status data. In that case, the image data containing the predetermined data and having a size based on the status data can be displayed on a viewing region. Thus, the novel data processing device can be highly convenient or reliable.

Note that in this specification, an “EL layer” refers to a layer provided between a pair of electrodes in a light-emitting element. Thus, a light-emitting layer containing an organic compound that is a light-emitting substance and being interposed between electrodes is one embodiment of the EL layer.

Note that in this specification, the device includes any of the following modules in its category: a module mounted with a flexible printed circuit (FPC) or a tape carrier package (TCP); a module having a TCP provided with a printed wiring board at the end thereof; and a module having an integrated circuit (IC) directly mounted by a chip on glass (COG) method over a substrate over which an element is formed.

In this specification, one of a first electrode and a second electrode of a transistor refers to a source electrode and the other refers to a drain electrode.

One embodiment of the present invention can provide a novel display panel that is highly convenient or reliable. Another embodiment of the present invention can provide a novel data processing device that is highly convenient or reliable. Another embodiment of the present invention can provide a novel human interface that is highly convenient or reliable. Another embodiment of the present invention can provide a novel display panel, a novel data processing device, or the like. Note that the description of these effects does not disturb the existence of other effects. One embodiment of the present invention does not necessarily have all the effects listed above. Other effects will be apparent from and can be derived from the description of the specification, the drawings, the claims, and the like.

### BRIEF DESCRIPTION OF DRAWINGS

In the accompanying drawings:

FIGS. 1A to 1C illustrate the structure of a display panel of an embodiment;

FIGS. 2A and 2B illustrate the structure of a display panel of an embodiment;

FIGS. 3A to 3C illustrate images displayed on a display panel of an embodiment;

FIG. 4 is a block diagram illustrating the structure of a data processing device of an embodiment;

FIG. 5 is a flow chart showing a program of an embodiment;

FIG. 6 is a flow chart showing a program of an embodiment;

FIGS. 7A to 7C are projection views illustrating the structure of a data processing device of an embodiment;

FIGS. 8A and 8B are projection views illustrating the structure of a data processing device of an embodiment;

FIGS. 9A to 9C illustrate the structure of a touch panel that can be used in a data processing device of an embodiment;

FIGS. 10A and 10B illustrate the structure of a touch panel that can be used in a data processing device of an embodiment;

FIGS. 11A to 11C each illustrate the structure of a touch panel that can be used in a data processing device of an embodiment;

FIGS. 12A to 12C each illustrate the structure of a touch panel that can be used in a data processing device of an embodiment;

FIG. 13 is a hexahedral view illustrating a data processing device of an embodiment; and

FIGS. 14A and 14B are a hexahedral view and a cross-sectional view illustrating a data processing device of an embodiment.

### BEST MODE FOR CARRYING OUT THE INVENTION

A display region where a first region, a first bendable region, and a second bendable region are arranged in stripes is included. The display region can be folded along a fold line formed in a first bendable region such that the ratio of the length of a short side of the first region to the length of a long side thereof is 0.9 times or more and 1.1 times or less the ratio of the length of a short side of the display region to the length of a long side thereof.

With such a structure, an image having approximately the same ratio of the vertical length to the horizontal length as an image displayed on the first region of the folded display panel can be displayed on the display region in an unfolded state. Thus, the novel display panel can be highly convenient or reliable.

Embodiments will be described in detail with reference to drawings. Note that the present invention is not limited to the description below, and it is easily understood by those skilled in the art that various changes and modifications can be made without departing from the spirit and scope of the present invention. Accordingly, the present invention should not be interpreted as being limited to the description of the embodiments below. Note that in the structures of the invention described below, the same portions or portions having similar functions are denoted by the same reference numerals in different drawings, and description of such portions is not repeated.

### Embodiment 1

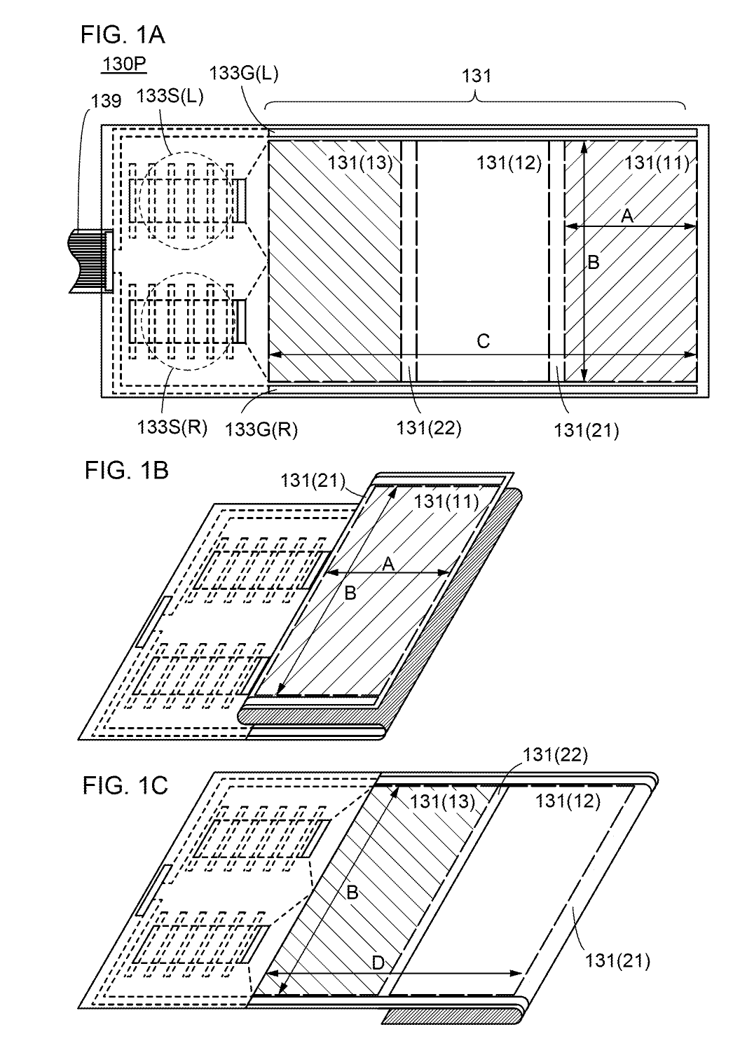

In this embodiment, structures of display panels of embodiments of the present invention will be described with reference to FIGS. 1A to 1C, FIGS. 2A and 2B, and FIGS. 3A to 3C.

FIGS. 1A and 1C illustrate the structure of a display panel of one embodiment of the present invention. FIG. 1A illustrates a state where a display panel 130P of one embodiment of the present invention is unfolded. FIGS. 1B and 1C are projection views each illustrating a state where the flexible display panel 130P in FIG. 1A is folded.

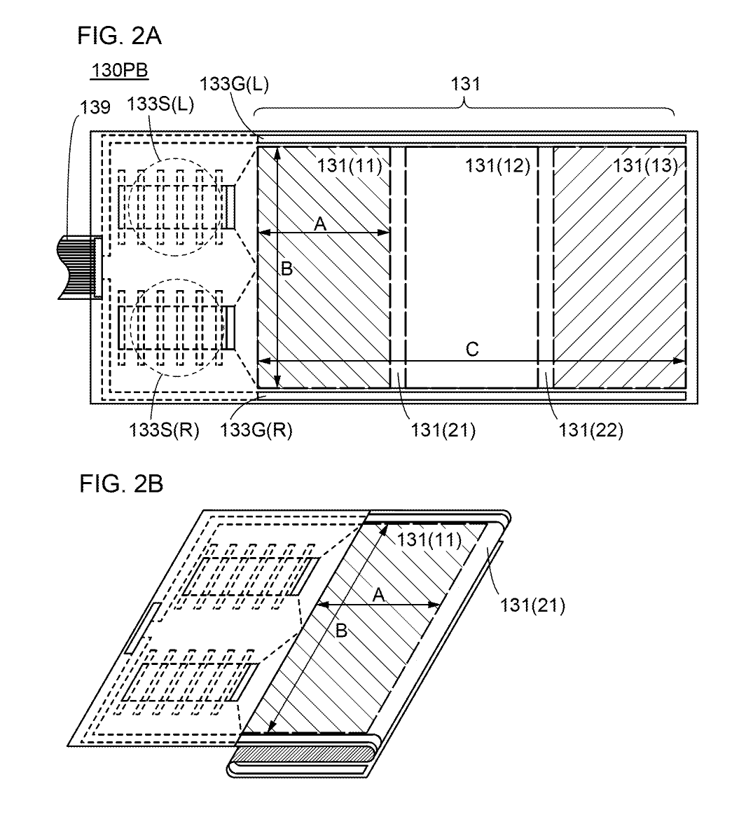

FIGS. 2A and 2B illustrate the structure of a display panel of one embodiment of the present invention that is different from the display panel in FIGS. 1A to 1C in arrangement of display regions. FIG. 2A illustrates an unfolded display panel 130PB of one embodiment of the present invention. FIG. 2B is a projection view illustrating the display panel 130PB in FIG. 2A that is folded.

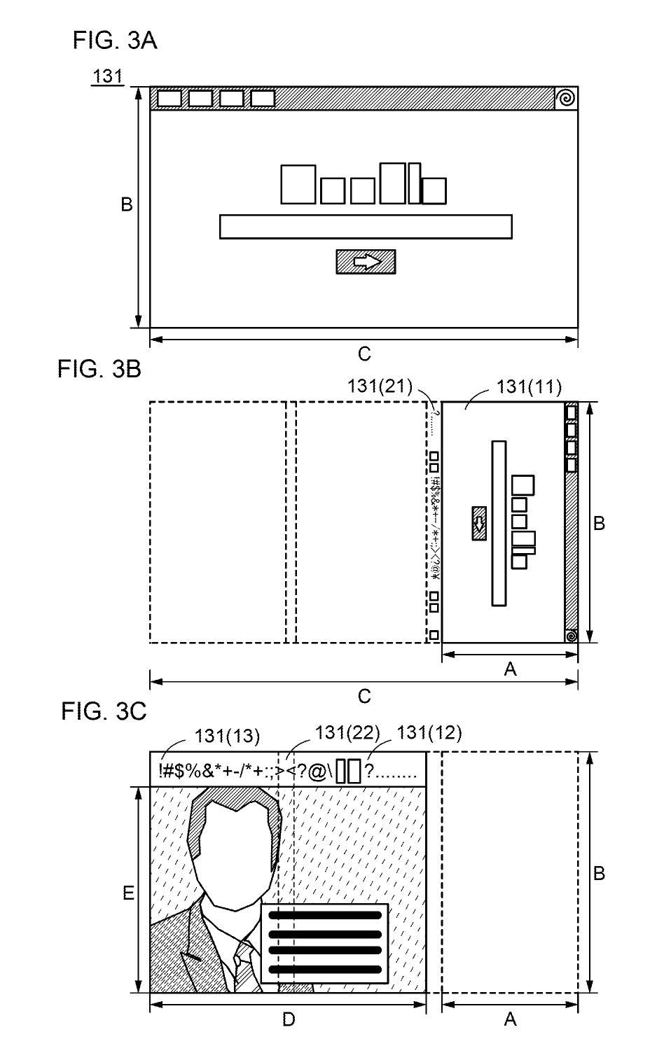

FIGS. 3A to 3C each illustrate an image displayed on a display panel of one embodiment of the present invention. FIG. 3A is a schematic view illustrating a second image displayed on a display region. FIG. 3B is a schematic view illustrating a first image displayed on a first region. FIG. 3C is a schematic view illustrating an image displayed on a second region and a third region.

### Structural Example of Display Panel

The display panel 130P described in this embodiment includes a display region 131 where a first region 131(11), a first bendable region 131(21), and a second region 131(12) are arranged in stripes in this order (see FIG. 1A).

The ratio of the length A of a short side of the first region 131(11) to the length B of a long side thereof (A/B) is 0.9 times or more and 1.1 times or less the ratio of the length B of a short side of the display region 131 to the length C of a long side thereof (B/C).

The display region 131 can be folded and unfolded along a fold line formed in the first bendable region 131(21).

The ratio of the length A of the short side of the first region 131(11) to the length B of the long side thereof is preferably approximately 9:16. Note that the ratio of A to B is approximately 9:16 in the case where the ratio of the length A of the short side to the length B of the long side (A/B) is greater than or equal to 0.50 and less than or equal to 0.62.

The display panel 130P described in this embodiment includes the display region 131 where the first region 131(11), the first bendable region 131(21), the second region 131(12), a second bendable region 131(22), and a third region 131(13) are arranged in stripes in this order. The display region 131 can be folded and unfolded along a first fold line formed in the first bendable region 131(21) and a second fold line formed in the second bendable region 131(22).

The ratio of the length A of a short side of the first region 131(11) to the length B of a long side thereof (A/B) is 0.9 times or more and 1.1 times or less the ratio of the length B of a short side of the display region 131 to the length C of a long side thereof (B/C).

The ratio of the length A of the short side of the first region 131(11) to the length B of the long side thereof is preferably approximately 9:16.

The display panel 130P described in this embodiment includes the display region 131 where the first region 131(11), the first bendable region 131(21), and the second bendable region 131(12) are arranged in stripes in this order. The display region 131 can be folded along the first bendable region 131(21) such that the ratio of the length A of the short side of the first region 131(11) to the length B of the long side thereof (A/B) is 0.9 times or more and 1.1 times or less the ratio of the length B of the short side of the display region 131 to the length C of the long side thereof (B/C) (FIGS. 3A and 3B).

With such a structure, an image having approximately the same ratio of the vertical length to the horizontal length as an image displayed on the first region of the display region in a folded state can be displayed on the display region in an unfolded state. Thus, the novel display panel can be highly convenient or reliable.

The display panel 130P may further be provided with a first scan line driver circuit 133G(L), a second scan line driver circuit 133G(R), a first signal line driver circuit 133S(L), and a second signal line driver circuit 133S(R).

The display panel 130P is electrically connected to a flexible printed circuit FPC 139.

Individual components included in the display panel 130P will be described below. Note that these components cannot be clearly distinguished and one component also serves as another component or include part of another component in some cases.

For example, a touch panel in which a touch sensor is provided so as to overlap with a display panel serves as a positional data input portion as well as a display portion.

### <<Overall Structure>>

The display panel 130P includes the display region 131 (see FIG. 1A).

The display panel 130P may further be provided with a first scan line driver circuit 133G(L), a second scan line driver circuit 133G(R), the first signal line driver circuit 133S(L), and the second signal line driver circuit 133S(R).

### <<Display Region>>

The display region 131 is supplied with image data and displays an image. Furthermore, the display region 131 includes a display element that displays an image based on image data.

The display region 131 includes the first region 131(11), the first bendable region 131(21), the second region 131(12), the second bendable region 131(22), and the third region 131(13).

The first region 131(11) has short sides and long sides. The length of the long side of the first region 131(11) is approximately equal to that of the short side of the display region 131.

The ratio of the length A of a short side of the first region 131(11) to the length B of a long side thereof (A/B) is 0.9 times or more and 1.1 times or less the ratio of the length B of a short side of the display region 131 to the length C of a long side thereof (B/C).

The display region 131 can be bent along the first bendable region 131(21) and the second bendable region 131(22). The first bendable region 131(21) and the second bendable region 131(22) each include a flexible substrate and a display element held by the flexible substrate.

For example, metal or resin can be used for the flexible substrate.

Specifically, a material such as aluminum, steel, SUS, or a magnesium alloy can be used for the flexible substrate.

Specifically, materials that contain polyester, polyolefin, polyamide (e.g., nylon and aramid), polyimide, polycarbonate, a resin having an acrylic bond, a urethane bond, an epoxy bond, or a siloxane bond, or the like can be used for the flexible substrate.

The first fold line is formed in the first bendable region 131(21) and the second fold line is formed in the second bendable region 131(22), and the display region 131 can be folded along the first fold line and the second fold line (see FIGS. 1B and 1C). In other words, the display region 131 can be folded along the first fold line formed by mountain-folding a surface of the first bendable region 131(21) that can perform display and the second fold line formed by valley-folding a surface of the second bendable region 131(22) that can perform display.

Furthermore, the first bendable region 131(21) and the second bendable region 131(22) can be repeatedly folded and unfolded. For example, image data can be displayed on a mountain fold line formed on the surface of the first bendable region 131(21) or the second bendable region 131(22) that can perform display.

FIG. 1B illustrates the display panel 130P folded such that image data can be displayed on the first region 131(11). FIG. 1C illustrates the display panel folded such that image data can be displayed on the third region 131(13).

Note that the display panel of one embodiment of the present invention is not limited to the one where a display region is located as illustrated in FIG. 1A.

For example, the first region 131(11) may be located on the side where the flexible printed circuit FPC 139 is located as in the display panel 130PB (see FIG. 2A).

FIG. 2B illustrates the display panel 130PB folded such that image data displayed on the first region 131(11) can be viewed.

Furthermore, the first region 131(11) may be located between the second region 131(12) and the third region 131(13).

The ratio of the length A of the short side to the length B of the long side of the first region 131(11) is preferably approximately 9:16, in which case the display region 131 can be used without waste and a wide and large image can be displayed.

The ratio of the length A of a short side of the first region 131(11) to the length B of a long side thereof (A/B) is 0.9 times or more and 1.1 times or less the ratio of the length B of a short side of the display region 131 to the length C of a long side thereof (B/C).

Specifically, the first bendable region 131(21) is provided such that the ratio of the length A of the short side of the first region 131(11) to the length B of the long side thereof is 9:16. In addition, the ratio of the length B of the short side of the display region 131 to the length C of the long side thereof can be 16:28.4 (≈16×16÷9).

Thus, the first image with a ratio of the vertical length to the horizontal length of 9:16 can be favorably displayed on the first region 131(11) (see FIG. 3B). Furthermore, the second image approximately similar to the first image can be favorably displayed on the display region 131 (see FIG. 3A). Note that the image illustrated in FIG. 3B can be referred to as a downsized image of FIG. 3A, and the image illustrated in FIG. 3A can be referred to as an enlarged image of FIG. 3B.

Furthermore, 1080×1920 pixels may be arranged in a matrix in the short side and long side directions such that an image that conforms to the standard of full high vision broadcast can be displayed.

The display region 131 is provided with display elements. For example, the display elements may be arranged in a matrix in the display region 131, and the display elements arranged in a matrix may be driven by a passive matrix method or an active matrix method.

Organic electroluminescent elements or any of various display elements such as display elements (electronic ink) that perform display by an electrophoretic method, an electronic liquid powder (registered trademark) method, an electrowetting method, or the like; MEMS shutter display elements; optical interference type MEMS display elements; and liquid crystal elements can be used.

A touch sensor is provided on the display panel 130P, whereby a touch panel can be formed. Specifically, the touch sensor may be placed on the display surface side of the display panel 130P, or the touch sensor and the display panel 130P may be integrated into one unit. In other words, either of an on-cell touch panel or an in-cell touch panel may be employed.

Note that specific examples of a structure that can be employed for the display panel 130P will be described in Embodiments 5 to 7.

Note that this embodiment can be combined with any of the other embodiments in this specification as appropriate.

### Embodiment 2

In this embodiment, the structure of a data processing device of one embodiment of the present invention will be described with reference to FIGS. 1A to 1C, FIGS. 2A and 2B, FIGS. 3A to 3C, and FIG. 4.

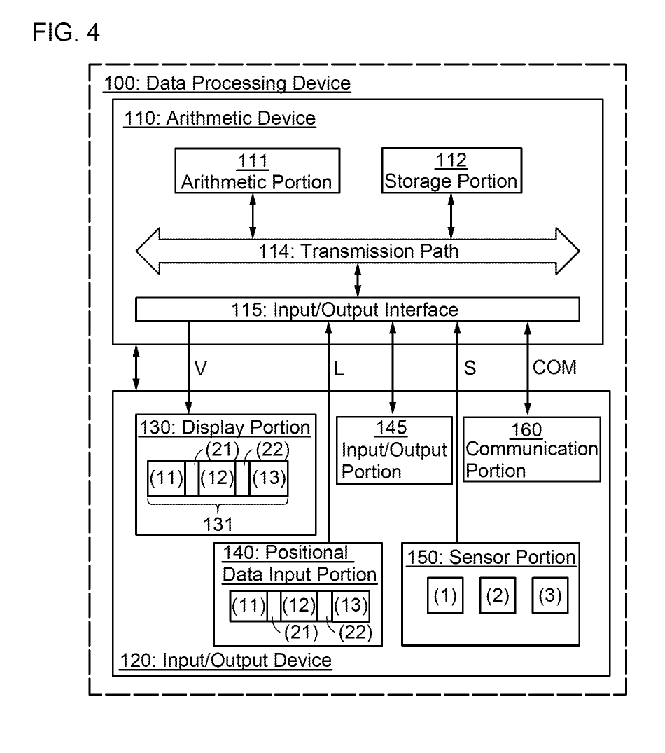

FIG. 4 illustrates the structure of the data processing device of one embodiment of the present invention. FIG. 4 is a block diagram illustrating the structure of the data processing device of one embodiment of the present invention.

### Structural Example of Data Processing Device

The data processing device 100 described in this embodiment includes an input/output device 120 that is supplied with image data V and supplies sensing data S, and an arithmetic device 110 that supplies the image data V and is supplied with the sensing data S (see FIG. 4).

The input/output device 120 includes the display portion 130 that is supplied with the image data V and the sensor portion 150 that supplies the sensing data S.

The display portion 130 includes a display region where the first region 131(11), the first bendable region 131(21), and the second region 131(12) are arranged in stripes in this order (see FIG. 1A).

The display portion 130 can be folded and unfolded along a first fold line formed in the first bendable region 131(21).

The sensor portion 150 determines whether the display portion 130 is folded or whether it is unfolded and supplies the sensing data S that contains data showing the determined state (see FIG. 4).

The arithmetic device 110 supplies the image data V containing a first image that fits the first region 131(11) in the case where the sensing data S contains data showing the folded state, and supplies the image data V containing a second image that is approximately similar to the first image and fits the display region 131 of the display portion 130 in the case where the sensing data S contains data showing the unfolded state (see FIG. 4).

The ratio of the vertical length of the second image to the horizontal length thereof is 0.9 times or more and 1.1 times or less the ratio of the vertical length of the first image to the horizontal length thereof.

The data processing device 100 described in this embodiment includes the input/output device 120 and the arithmetic device 110. The input/output device 120 includes the display portion 130 and the sensor portion 150. The display portion 130 is supplied with the image data V and can be folded. The sensor portion 150 determines whether the display portion 130 is folded or whether it is unfolded and supplies the sensing data S containing the determined state. The arithmetic device 110 supplies the image data V and is supplied with the sensing data S.

With such a structure, the second image having approximately the same ratio of the vertical length to the horizontal length as the first image that can be displayed so as to fit the first region of the folded display portion can be displayed so as to fit the display region of the unfolded display portion. Thus, the novel data processing device can be highly convenient or reliable.

The input/output device 120 may be provided with a positional data input portion 140 capable of supplying positional data L, an input/output portion 145 that supplies and is supplied with data, and a communication portion 160 that supplies and is supplied with communication data COM.

The arithmetic device 110 may include an arithmetic portion 111, a storage portion 112 that stores a program to be executed by the arithmetic portion 111, a transmission path 114 that supplies and is supplied with data, and an input/output interface 115 that supplies and is supplied with data.

Individual components included in the data processing device will be described below. Note that these components cannot be clearly distinguished and one component also serves as another component or include part of another component in some cases.

For example, a touch panel in which a touch sensor is provided so as to overlap with a display panel serves as the positional data input portion 140 as well as the display portion 130.

Note that although a touch sensor having a structure where the positional data input portion 140 is placed on the display surface side of the display portion 130 is described as an example in this embodiment, one embodiment of the present invention is not limited to this structure. Specifically, the touch sensor may be placed on the sensing surface side of the positional data input portion 140, or the display portion 130 and the positional data input portion 140 may be integrated into one unit. In other words, either of an on-cell touch panel or an in-cell touch panel may be employed.

### <Overall Structure>

The data processing device 100 includes the input/output device 120 and the arithmetic device 110 (see FIG. 4).

### <<Input/Output Device 120>>

The input/output device 120 includes the display portion 130, the positional data input portion 140, an input/output portion 145, the sensor portion 150, and the communication portion 160.

### <<Display Portion 130>>

The display portion 130 is supplied with the image data V and can display the image data V (see FIG. 4).

The display portion 130 includes the display region 131 and displays the image data V on the display region 131.

The display region 131 includes the first display region 131(11), the first bendable region 131(21), the second display region 131(12), the second bendable region 131(22), and the third display region 131(13).

The ratio of the length of a short side of the first display region 131(11) to the length of a long side thereof is 0.9 times or more and 1.1 times or less the ratio of the length of a short side of the display region to the length of a long side thereof.

The first bendable region 131(21) and the second bendable region 131(22) can display the image data V and can be bent.

For example, the first bendable region 131(21) and the second bendable region 131(22) can be bent with a radius of curvature of 10 mm or less, preferably 8 mm or less, more preferably 5 mm or less, still more preferably 4 mm or less.

The display portion 130 can be folded such that a first fold line is formed in the first bendable region 131(21) and can be unfolded along the first fold line.

The display portion 130 can be folded such that a second fold line is formed in the second bendable region 131(22) and can be unfolded along the second fold line.

The first region 131(11) and the second region 131(12) may be driven together. For example, one scan line driver circuit may supply signals to select scan lines.

The first region 131(11) and the second region 131(12) may be driven separately. For example, separate scan line driver circuits may be provided for the regions, and the scan line driver circuits may supply signals to select scan lines to the corresponding display portions.

For example, while the data processing device 100 is in the standby state, only the first region (11) and/or the first bendable region (21) may be driven and the driving of the other regions may be stopped. Alternatively, while the data processing device 100 is folded, only the first region (11) and/or the first bendable region (21) may be driven and the driving of the other regions that cannot be viewed may be stopped. Stopping the driving of the other regions can reduce power consumption.

For example, the display panel described in Embodiment 1 can be used for the display portion 130.

Note that specific examples of a structure that can be employed for the display portion 130 will be described in Embodiments 5 to 7.

### <<Sensor Portion 150>>

The sensor portion 150 can determine the states of the data processing device 100 and/or the circumstances and supply the sensing data S (see FIG. 4).

The sensor portion 150 is provided with a sensing circuit 150(1), a sensing circuit 150(2), and a sensing circuit 150(3) that determines whether the display portion 130 is folded or whether it is unfolded.

The sensor portion 150 supplies the sensing data S containing data that shows the folded or unfolded state of the display portion 130.

The folded or unfolded state of the display portion 130 can be sensed by various sensors.

The folded state of the display portion 130 can be sensed by, for example, a mechanical switch, an optical switch, a magnetic sensor, a photoelectric conversion element, a MEMS pressure sensor, or a pressure-sensitive sensor.

For example, an object that obstructs display of the second region 131(12) or the third region 131(13) is sensed, whereby the folded state of the display portion 130 can be sensed.

Specifically, the photoelectric conversion element is provided in the data processing device 100 such that the second region 131(12) can determine the intensity of light incident from the surface side where the image data V is displayed, and the third region 131(13) is sensed by the photoelectric conversion element to determine whether the display portion 130 is folded along the second bendable region 131(22).

Note that the sensor portion 150 may sense acceleration, angular acceleration, a direction, pressure, a global positioning system (GPS) signal, temperature, humidity, or the like and supply data thereon.

### <<Positional Data Input Portion 140>>

The positional data input portion 140 senses an approaching object and supplies positional data L of the approaching object.

For example, a user of the data processing device 100 can supply a variety of operating instructions to the data processing device 100 by making his/her finger, palm, or the like in proximity to the positional data input portion 140.

For example, an operating instruction including a termination instruction (an instruction to terminate the program) can be supplied.

The positional data input portion 140 is provided with a first positional data input portion 140(11), a second positional data input portion 140(12), a third positional data input portion 140(13), a fourth positional data input portion 140(21), and a fifth positional data input portion 140(22).

The positional data input portion 140 may be provided so as to overlap with the display portion 130.

Specifically, the first positional data input portion 140(11) is provided so as to overlap with the first display region 131(11), the second positional data input portion 140(12) is provided so as to overlap with the second display region 131(12), the third positional data input portion 140(13) is provided so as to overlap with the third display region 131(13), the fourth positional data input portion 140(21) that is bendable is provided so as to overlap with the first bendable region 131(21), and the fifth positional data input portion 140(22) that is bendable is provided so as to overlap with the second bendable region 131(22).

Note that in the case where the positional data input portion 140 is provided on the side closer to a user than the display portion 130, the positional data input portion 140 that has a light-transmitting property is provided.

The first positional data input portion 140(11) can be driven either together with or separately from any of the other positional data input portions.

For example, in the case where the sum of power consumed by the first positional data input portion 140(11) and power consumed by the second positional data input portion 140(12) is larger than power consumed by the first positional data input portion 140(11), only the first positional data input portion 140(11) may be driven and the drive of the second positional data input portion 140(12) may be stopped in a standby state of the data processing device 100. Stopping the drive of the second positional data input portion 140(12) can reduce power consumption.

For example, a proximity sensor can be used for the positional data input portion 140. The proximity sensor senses the proximity or touch of a target (e.g., a finger or a palm), and a capacitor or an imaging element can be used as the proximity sensor. Note that a substrate provided with capacitors arranged in a matrix can be referred to as a capacitive touch sensor, and a substrate provided with an imaging element can be referred to as an optical touch sensor.

Note that structural examples that can be used for the positional data input portion 140 that is flexible and bendable will be described in Embodiments 5 to 7.

### <<Communication Portion 160>>

The communication portion 160 supplies data COM supplied by the arithmetic device 110 to a device or a communication network outside the data processing device 100. Furthermore, the communication portion 160 acquires the data COM from the device or communication network outside the data processing device 100 and supplies the data COM.

The data COM can contain a variety of instructions or the like in addition to phonetic data, image data, or the like. For example, the data COM can contain an operating instruction to make the arithmetic portion 111 generate or delete the image data V.

A communication means for connection to the external device or external communication network, e.g., a hub, a router, or a modem, can be used for the communication portion 160. Note that the connection method is not limited to a method using a wire, and a wireless method (e.g., radio waves or infrared rays) may be used.

### <<Input/Output Portion 145>>

As the input/output portion 145, for example, a camera, a microphone, a read-only external storage portion, an external storage portion, a scanner, a speaker, or a printer can be used.

Specifically, as a camera, a digital camera, digital video camera, or the like can be used.

As an external storage portion, a hard disk, a removable memory, or the like can be used. As a read-only external storage portion, a CD-ROM, a DVD-ROM, or the like can be used.

### <<Arithmetic Device>>

The arithmetic device 110 includes the arithmetic portion 111 and the storage portion 112. The arithmetic device 110 supplies the image data V and is supplied with the sensing data S (see FIG. 4).

For example, the arithmetic device 110 supplies the image data V containing an image for operation of the data processing device 100.

Note that the image data V is displayed on the display region 131 of the display portion 130.

The arithmetic device 110 may be configured to be supplied with the positional data L. For example, by touching the position of the positional data input portion 140 overlapping with the image used for operation, which is displayed on the display portion 130, with a finger or the like, a user can supply an operating instruction associated with the image to the arithmetic device 110.

The arithmetic device 110 may further include the transmission path 114 and the input/output interface 115.

### <<Arithmetic Portion>>

The arithmetic portion 111 executes the program stored in the storage portion 112. For example, in response to supply of the positional data L of a position in which an image used for operation is displayed, the arithmetic portion 111 executes a program associated with the image.

### <<Storage Portion>>

The storage portion 112 stores the program to be executed by the arithmetic portion 111.

Note that an example of the program to be executed by the arithmetic device 110 will be described in Embodiment 3.

### <<Input/Output Interface and Transmission Path>>

The input/output interface 115 supplies data and is supplied with data.

The transmission path 114 can supply data, and the arithmetic portion 111, the storage portion 112, and the input/output interface 115 are supplied with data. In addition, the arithmetic portion 111, the storage portion 112, and the input/output interface 115 can supply data, and the transmission path 114 is supplied with data.

### <<Housing>>

The data processing device 100 may include a housing to protect the arithmetic device 110 or the like from various kinds of stresses applied to the data processing device 100.

Metal, plastic, glass, ceramics, or the like can be used for the housing.

This embodiment can be combined with any of the other embodiments in this specification as appropriate.

### Embodiment 3

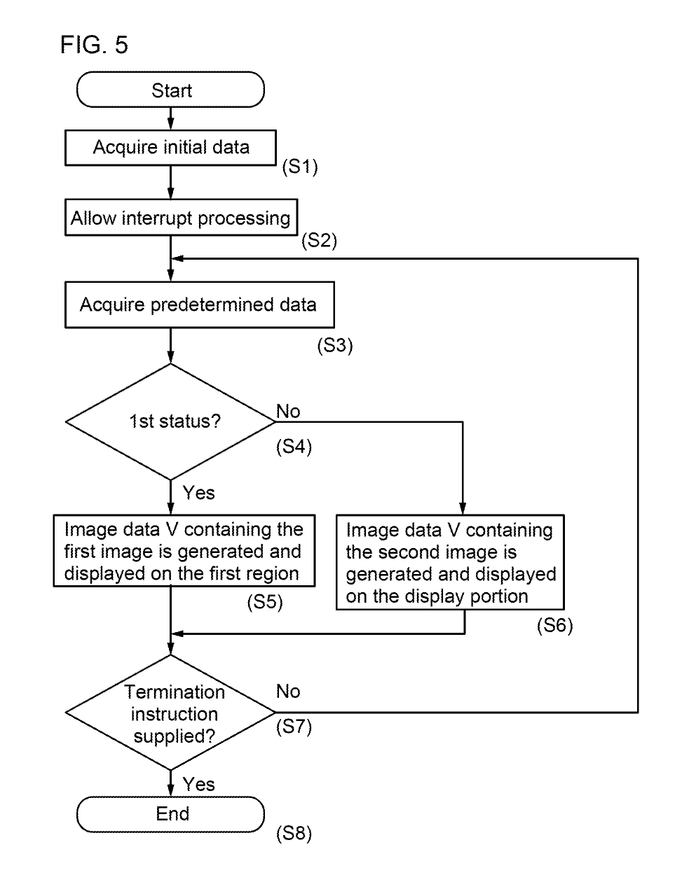

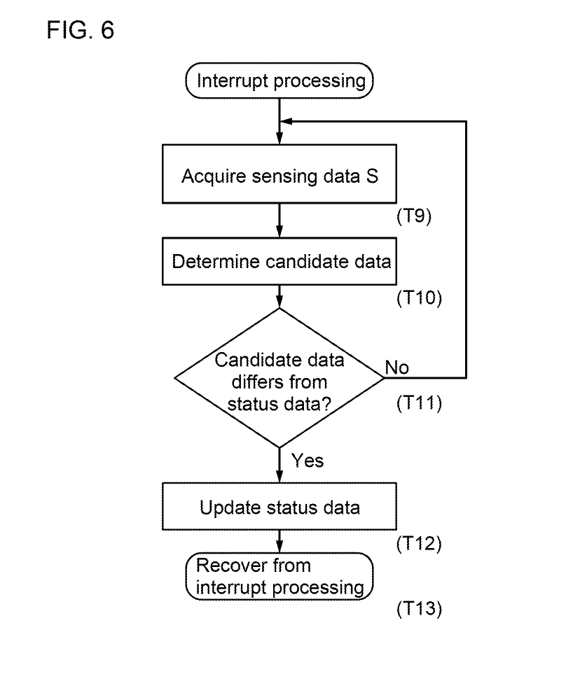

In this embodiment, a structure of a program that can be used in the data processing device of one embodiment of the present invention will be described with reference to FIGS. 5 and 6.

FIG. 5 is a flow chart of a program that is executed by an arithmetic device of the data processing device of one embodiment of the present invention. FIG. 6 is a flow chart illustrating an interrupt processing of a program described with reference to FIG. 5.

### Structural Example of Data Processing Device

The data processing device 100 described in this embodiment includes the arithmetic portion 111 and the storage portion 112 that stores a program to be executed by the arithmetic portion 111.

The program stored by the storage portion 112 includes the following steps.

### <<First Step>>

In a first step, initial data containing status data is acquired (S1 in FIG. 5).

For example, the initial data that contains predetermined status data stored by the storage portion 112 and necessary data used in a later step are acquired. The initial data may contain the sensing data S supplied from the sensor portion 150.

Specifically, the status data showing a first status or a second status is acquired. In the first status, the sensing data S supplied from the sensor portion 150 contains data that shows the state where the display portion 130 is folded. In the second status, the sensing data S supplied from the sensor portion 150 contains data that shows the state where the display portion 130 is unfolded.

### <<Second Step>>

In a second step, interrupt processing is allowed (S2 in FIG. 5). Note that when the interrupt processing is allowed, the arithmetic portion 111 can receive an instruction to execute the interrupt processing. When the interrupt processing is allowed, the arithmetic portion 111 stops the main processing, executes the interrupt processing, and stores the execution result in the storage portion, for example. Consequently, the arithmetic portion that has recovered from the interrupt processing can resume the main processing on the basis of the stored execution result of the interrupt processing.

### <<Third Step>>

In a third step, predetermined data is acquired (S3 in FIG. 5).

The predetermined data contains data that is the basis for the first image or the second image that is to be generated in a later step.

For example, data containing an image before the area occupied by the image is optimized so as to fit the area of the first region 131(11) or the display region is acquired.

When the program proceeds from a seventh step to the third step, an operating instruction or updated status data supplied by the interrupt processing is reflected in the third step.

### <<Fourth Step>>

In a fourth step, a fifth step is selected when the status data shows a first status, or a sixth step is selected when the status data shows a second status (S4 in FIG. 5).

### <<Fifth Step>>

In a fifth step, the image data V containing the first image is generated on the basis of data acquired in the third step so as to fit the first region 131(11), and the image data V is displayed (S5 in FIG. 5).

For example, the image data V in which the area occupied by an image is adjusted so that the image fits the first region 131(11) on the basis of the image data V acquired in the third step.

For example, when data containing numerics and alphabets is acquired in the third step and the folded state of the display portion 130 is sensed, the image data V containing the first image where numeric or alphabets are arranged in the first region in a landscape position so as to be easily read is generated.

### <<Sixth Step>>

In a sixth step, the image data V containing the second image is generated so as to fit the display region of the display portion on the basis of data acquired in the third step, and the image data V is displayed (S6 in FIG. 5).

For example, the image data V whose size is adjusted so as to fit the display region of the display portion is generated on the basis of the image data V acquired in the third step.

For example, when data containing numerics and alphabets is acquired in the third step and the unfolded state of the display portion 130 is sensed, the image data V containing the second image where numerics or alphabets are arranged in the display portion 130 in a landscape position so as to be easily read.

### <<Seventh Step>>

In a seventh step, an eighth step is selected when a termination instruction is supplied in the interrupt processing, or the third step is selected when no termination instruction is supplied in the interrupt processing (S7 in FIG. 5).

### <<Eighth Step>>

In the eighth step, the program terminates (S8 in FIG. 5).

### <<Interrupt Processing>>

The interrupt processing includes the following steps.

### <<Ninth Step>>

In a ninth step, the sensing data S is acquired (T9 in FIG. 6).

For example, the sensing data S supplied from the sensor portion 150 is acquired using a timer or the like. Specifically, the sensing data S containing data that shows the folded or unfolded state of the display portion 130 is acquired.

### <<Tenth Step>>

In a tenth step, candidate data is determined based on the sensing data S (T10 in FIG. 6).

### <<Eleventh Step>>

In an eleventh step, a twelfth step is selected when the candidate data differs from the status data, or the ninth step is selected when the candidate data is the same as the status data (T11 in FIG. 6).

### <<Twelfth Step>>

In the twelfth step, the status data is updated to the candidate data (T12 in FIG. 6).

For example, the status data is updated when there is a change in the sensing data S. Specifically, the status data is updated when there is a change in data that shows the folded or unfolded state of the display portion 130.

### <<Thirteenth Step>>

In the thirteenth step, the operation recovers from the interrupt processing (see T13 in FIG. 6).

Note that the status data updated in the interrupt processing is reflected after the program proceeds from the seventh step to the third step. The program proceeds to the eighth step and terminates when a termination instruction is supplied in the interrupt processing.

The data processing device described in this embodiment is configured to perform a step of acquiring the sensing data S containing whether the display portion is folded or whether it is unfolded and determining candidate data, a step of updating the status data to the candidate data in the case where the status data is different from the candidate data, and a step of generating the image data V containing predetermined data on the basis of the updated status data and displaying the image data V. Thus, image data that contains the predetermined data and has a size based on the status data can be displayed on a predetermined region. Consequently, the novel data processing device can be highly convenient or reliable.

### Modification Example 1 of Data Processing Device

As Modification Example 1 of this embodiment, a modification example of a program that can be used for the data processing device of one embodiment of the present invention will be described with reference to FIGS. 3A to 3C and FIG. 5.

Modification Example 1 is different from the data processing device 100 described in this embodiment in that the area occupied by the second image contained in the image data V generated in the sixth step in the above program is larger than the area occupied by the first image contained in the image data V generated in the fifth step. Here, different steps will be described below. Refer to the above description for similar steps.

### <<Sixth Step>>

In the sixth step, the image data V that contains the second image larger than the first image generated in the fifth step is generated so as to fit the display region of the display portion on the basis of data acquired in the third step, and the image data V is displayed (S6 in FIG. 5).

For example, the image data V containing the second image larger than the first image that occupies the first region 131(11) whose size is approximately one third of the display region 131 can be generated and displayed on the whole display region 131 (see FIGS. 3A and 3B).

The area occupied by the image displayed on the display portion is increased in accordance with a change in the status data from the folded state to the unfolded state of the display portion. Furthermore, the area occupied by an image displayed on the display portion is decreased in accordance with a change in the status data from the unfolded state to the folded state of the display portion. Specifically, the image is displayed so as to have a size three times as large as that in a folded state or one third as large as that in an unfolded state.

Alternatively, the first image is generated such that the vertical length or the horizontal length of the first image is 0.9 times or more the length A of the short side of the first region 131(11) or the length B of the long side thereof, and the second image is generated such that the vertical length or the horizontal length of the second image is 0.9 times or more the length B of the short side of the display region 131 or the length C of the long side thereof.

Consequently, an image having approximately the same ratio of the vertical length to the horizontal length, that is, an approximately similar image can be displayed by being downsized or enlarged in accordance with the size of the first region of the folded display portion or the size of the unfolded display portion. Thus, the novel data processing device can be highly convenient or reliable.

### Modification Example 2 of Data Processing Device

As Modification Example 2 of this embodiment, a modification example of a program that can be used for the data processing device of one embodiment of the present invention will be described with reference to FIGS. 3A to 3C and FIG. 5.

Modification Example 2 is different from the data processing device 100 described in this embodiment in that the image data V containing the third image outside the first image or the second image is generated in the fifth step or the sixth step in the above program. Here, different steps will be described below. Refer to the above description for similar steps.

### <<Fifth Step>>

In the fifth step, the image data V that contains the first image is generated so as to fit the first region 131(11) on the basis of data acquired in the third step, and the image data V containing the third image is displayed outside the region where the first image is displayed (S5 in FIG. 5).

### <<Sixth Step>>

In the sixth step, the image data V that contains the second image is generated so as to fit the display region of the display portion on the basis of data acquired in the third step, and the image data V containing the third image is displayed outside the region where the second image is displayed (S6 in FIG. 5).

Thus, the image data V containing the third image can be displayed outside the region where the first image or the second image is displayed. As a result, the novel data processing device can be highly convenient or reliable.

For example, the image data V containing the third image containing text data that is located outside the first image or the second image may be generated and displayed. Specifically, the image data V may be displayed on the first bendable region 131(21) (see FIG. 3B).

Note that the outside of the first image or the outside of the second image can be referred to as the frame of the first image or the frame of the second image.

The third image that moves as if it streams may be displayed. Furthermore, the direction in which text included in the third image moves may be changed according to the rule of a language that is displayed. For example, English text may move from right to left, and Arabian text may move from left to right. The speed at which text moves may be changed to meet the user's needs.

Text data or the like may be superimposed on the first image or the second image.

The third image may include a phone number, a temperature, a received e-mail, or the like.

Note that in the fifth step in the above program, the image data V containing the first image may be generated so as to fit a region other than the first region 131(11) in the case where the state where the display portion is folded in half along the first bendable region 131(21), and the image data V may be displayed on the region other than the first region (FIG. 3C). Accordingly, an image with a ratio of the horizontal length D to the vertical length E of approximately 3:4 can be favorably displayed.

The image data V may be generated such that the first image is located on the upper side or the lower side of the region other than the first region so as to fit the region other than the first region.

The first image can include image data broadcasted on television or the like as well as a software keyboard, text, and a photograph image.

### Modification Example 3 of Data Processing Device

As Modification Example 3 of this embodiment, a modification example of a program that can be used for the data processing device of one embodiment of the present invention will be described with reference to FIG. 6.

In the data processing device 100 described as Modification Example 3 of this embodiment, the sensor portion 150 determines the position of the display portion 130 and supplies the sensing data S containing data that shows the determined position.

The arithmetic device 110 determines the direction of the first image or the second image on the basis of the sensing data S and generates the image data V containing the first image or the second image located in the determined direction.

The data processing device 100 includes the sensor portion 150 and the arithmetic device 110. The sensor portion 150 determines the position of the display portion 130 and supplies the sensing data S containing data that shows the determined position. The arithmetic device 110 generates the image data V in accordance with the determined position. Thus, an image can be displayed on the display portion in the direction determined in accordance with the position of the display portion. Accordingly, the novel data processing device can be highly convenient or reliable.

For example, in the case where the position of the folded display portion 130 where the first region is used in a portrait mode or the position of the unfolded display portion 130 used in a portrait mode is sensed, text in the third image may be displayed vertically.

Modification Example 3 is different from the data processing device 100 described in this embodiment in the following points. The data processing device 100 of Modification Example 3 includes the sensor portion 150 that can determine the position of the display portion 130. In the first step in the above-described program, status data containing a combination of data that shows the folded or unfolded state of the display portion 130 and data that shows the position of the display portion 130 is acquired; in the fifth or sixth step, the direction in which the first image or the second image is displayed is determined based on the status data where the data that shows the position is combined, and the image data V containing the first image or the second image located in the determined direction is generated; in the ninth step, the sensing data S containing data that shows the position of the display portion 130 as well as data that shows the folded or unfolded state of the display portion 130 is acquired; and in the twelfth step, the status data is updated in the case where there are changes in the data that shows the position of the display portion as well as data that shows the folded or unfolded state of the display portion. Here, different components of the sensor portion 150 and different steps will be described, and the above description is referred to for similar components of the sensor portion 150 and similar steps.

### <<Sensor Portion 150>>

The sensor portion 150 determines the position of the display portion 130 and supplies the sensing signal S containing data that shows the position of the display portion 130. For example, an acceleration sensor or an angular acceleration sensor can be used as the sensor that determines the position of the display portion 130.

The sensor that determines the position of the display portion 130 is provided in a housing, for example.

### Modification Example of First Step

In a first step, initial data containing status data is acquired (S1 in FIG. 5).

Specifically, the status data showing a first status or a second status is acquired. In the first status, the sensing data S supplied from the sensor portion 150 contains data that shows the state where the display portion 130 is folded. In the second status, the sensing data S supplied from the sensor portion 150 contains data that shows the state where the display portion 130 is unfolded. Furthermore, data that shows whether the position of the display portion 130 is a landscape position or whether it is a portrait position is added to each status data to define four kinds of extended status data. The four kinds of extended status data are used.

### Modification Example of Fifth Step

In a fifth step, the image data V containing the first image is generated so as to fit the first region 131(11) on the basis of the data showing the folded state of the display portion and the position of the display portion that is acquired in the third step, and the image data V is displayed (S5 in FIG. 5).

For example, the image data V whose direction and size are adjusted so that the image fits the first region 131(11) in a landscape or portrait position is generated on the basis of the image data V acquired in the third step and the data showing the position of the display portion.

### Modification Example of Sixth Step

In a sixth step, the image data V containing the second image is generated so as to fit the display region of the display portion on the basis of the data showing the unfolded state of the display portion and the position of the display portion that is acquired in the third step, and the image data V is displayed (S6 in FIG. 5).

For example, the image data V whose direction and size are adjusted so that the image fits the display region of the display portion in a landscape or portrait position is generated on the basis of the status data acquired in the third step and the data showing the position of the display portion.

### Modification Example of Ninth Step

In a ninth step, the sensing data S that shows the position of the display portion is acquired (T9 in FIG. 6).

For example, the sensing data S containing data that shows the folded or unfolded state of the display portion 130 and data that shows the position of the display portion is acquired.

### Modification Example of Twelfth Step

In the twelfth step, the status data is updated to the candidate data (T12 in FIG. 6).

Specifically, when there is a change in data that shows the folded or unfolded state of the display portion 130, the status data is updated. Specifically, the status data is updated when there are a change in data that shows the position of the display portion as well as a change in data that shows the folded or unfolded state of the display portion 130.

This embodiment can be combined with any of the other embodiments in this specification as appropriate.

### Embodiment 4

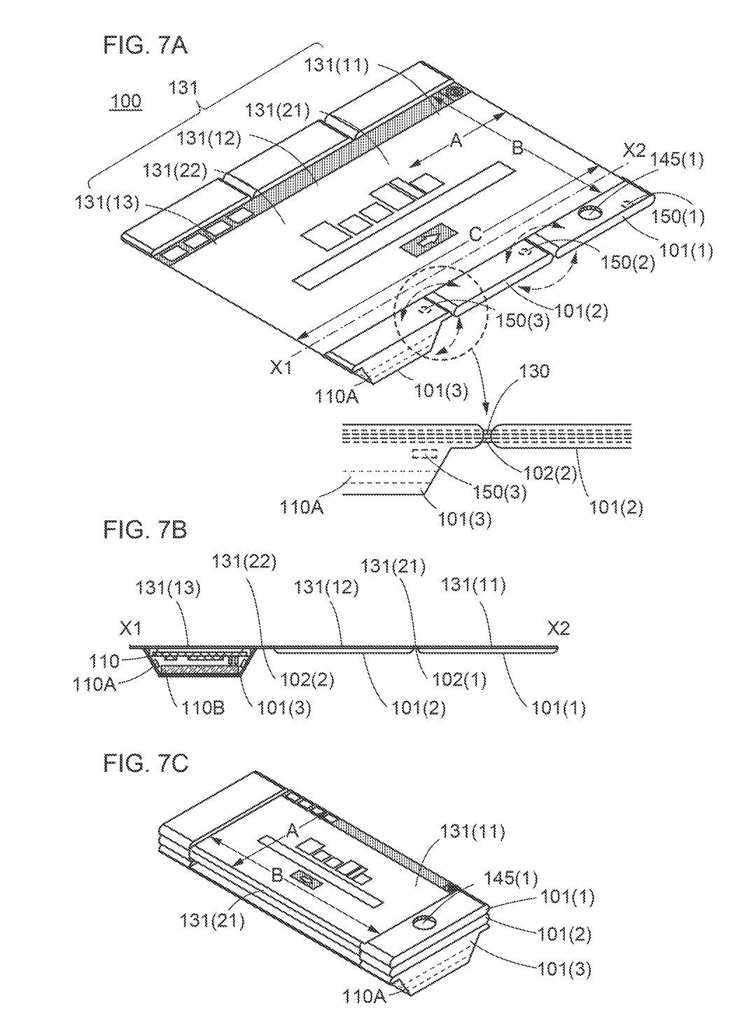

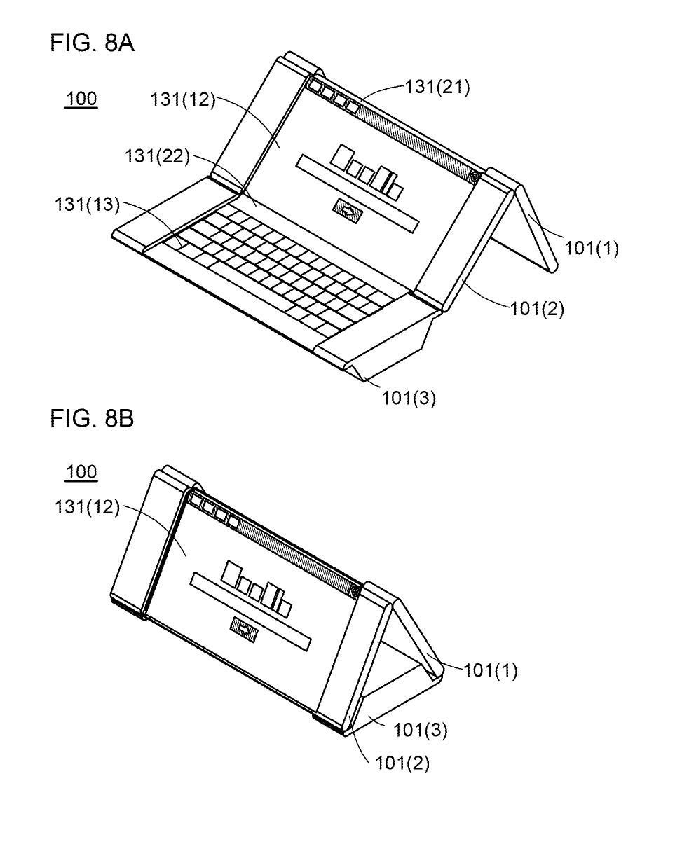

In this embodiment, the structure of a data processing device of one embodiment of the present invention will be described with reference to FIG. 4, FIGS. 7A to 7C, and FIGS. 8A and 8B.

FIG. 4 is a block diagram illustrating the structure of the data processing device of one embodiment of the present invention.

FIGS. 7A to 7C, and FIGS. 8A and 8B illustrate the data processing device of one embodiment of the present invention.

FIG. 7A is a projection view illustrating the display portion 130 of the data processing device 100 of one embodiment of the present invention that is unfolded. FIG. 7B is a cross-sectional view of the data processing device 100 along X1-X2 in FIG. 7A. FIG. 7C is a projection view illustrating the display portion 130 that is folded.

FIG. 8A is a projection view illustrating the display portion 130 of the data processing device 100 of one embodiment of the present invention that is folded. FIG. 8B is a projection view illustrating the display portion 130 that is folded in a manner different from that in FIG. 8A.

### Structural Example of Data Processing Device

The data processing device 100 described in this embodiment includes the input/output device 120 that is supplied with the image data V and supplies the sensing data S, and the arithmetic device 110 that supplies the image data V and is supplied with the sensing data S (see FIG. 4).

The input/output device 120 includes the display portion 130 that is supplied with the image data V and the sensor portion 150 that supplies the sensing data S.

The display portion 130 includes a display region where the first region 131(11), the first bendable region 131(21), the second region 131(12), the second bendable region 131(22), and the third region 131(13) are arranged in stripes in this order (see FIG. 4 and FIG. 7A).

The ratio of the length A of the short side of the first region 131(11) to the length B of the long side thereof (A/B) is 0.9 times or more and 1.1 times or less the ratio of the length B of the short side of the display region 131 to the length C of the long side thereof (B/C).

The ratio of the length A of the short side of the first region 131(11) to the length B of the long side thereof is approximately 9:16.

The display portion 130 can be folded and unfolded along a first fold line formed in the first bendable region 131(21) and a second fold line formed in the second bendable region 131(22) (see FIGS. 7A and 7C).

The sensor portion 150 determines whether the display portion 130 is folded or whether it is unfolded and supplies the sensing data S that contains data showing the determined state (see FIG. 4).

The arithmetic device 110 supplies the image data V containing the first image that fits the first region 131(11) in the case where the sensing data S shows the folded state, and supplies the image data V containing the second image that is approximately similar to the first image and fits the display region 131 of the display portion 130 in the case where the sensing data S shows the unfolded state (see FIG. 4 and FIGS. 7A to 7C).

The area of the second image is 2.7 times or more and 3.3 times or less that of the first image.

The data processing device 100 described in this embodiment includes the input/output device 120 and the arithmetic device 110. The input/output device 120 includes the display portion 130 and the sensor portion 150. The display portion 130 is supplied with the image data V and can be folded. The sensor portion 150 determines whether the display portion 130 is folded or whether it is unfolded and supplies the sensing data S containing the determined state. The arithmetic device 110 supplies the image data V and is supplied with the sensing data S.

With such a structure, the second image having approximately the same ratio of the vertical length to the horizontal length as the first image that can be displayed so as to fit the first region of the folded display portion can be displayed so as to fit the display region of the unfolded display portion (see FIG. 7A). Thus, the novel data processing device can be highly convenient or reliable.

A housing 101(1), a hinge 102(1), a housing 101(2), a hinge 102(2), and a housing 101(3) are positioned in this order such that the display portion 130 can be held, folded, and unfolded (see FIGS. 7A to 7C).

The housing 101(1) overlaps with the first region 131(11) and is provided with the sensing circuit 150(1) and a button 145(1).

The housing 101(2) overlaps with the second region 131(12) and is provided with the sensing circuit 150(2).

The housing 101(3) overlaps with the third region 131(13) and is provided with the sensing circuit 150(3). The arithmetic device 110, an antenna 110A, and a battery 110B are provided in the housing 101(3).

The hinge 102(1) overlaps with the first bendable region 131(21) and connects the housing 101(1) and the housing 101(2) such that the housing 101(1) can be rotated with respect to the housing 101(2) (see FIG. 7B).

The hinge 102(2) overlaps with the second bendable region 131(22) and connects the housing 101(2) and the housing 101(3) such that the housing 101(2) can be rotated with respect to the housing 101(3).

The antenna 110A is electrically connected to the arithmetic device 110 and supplies or is supplied with a signal.

In addition, the antenna 110A is wirelessly supplied with power from an external device and supplies the power to the battery 110B.

The battery 110B is electrically connected to the arithmetic device 110 and supplies or is supplied with power.

Individual components included in the data processing device 100 will be described below. Note that these components cannot be clearly distinguished and one component also serves as another component or include part of another component in some cases.

For example, a touch panel in which a touch sensor overlaps with a display panel serves as the positional data input portion 140 as well as the display portion 130.

Note that although this embodiment describes a touch sensor having a structure where the positional data input portion 140 is placed on the display surface side of the display portion 130 as an example, one embodiment of the present invention is not limited to this structure. Specifically, the display portion 130 may be placed on the sensing surface side of the positional data input portion 140, or the display portion 130 and the positional data input portion 140 may be integrated into one unit. In other words, either of an on-cell touch panel or an in-cell touch panel may be employed.

### <<Overall Structure>>

The data processing device 100 includes the input/output unit 120 and the arithmetic device 110 (see FIG. 4).

The data processing device 100 described in this embodiment is different from that described in Embodiment 2 in the structures of the housing 101(1), the housing 101(2), the housing 101(3), the hinge 102(1), the hinge 102(2), the antenna 110A, the battery 110B, and the button 145(1). Different portions will be described here, and the above description is referred to for the other similar portions.

### <<Display Portion 130>>

The display portion 130 described in this embodiment is different from that described in Embodiment 2 in that the ratio of the length A of the short side to the length B of the long side of the first region 131(11) of the display portion 130 described in Embodiment 2 is approximately 9:16. Thus, a wide image can be displayed (see FIG. 7C).

Furthermore, 1080×1920 pixels may be arranged in a matrix in the short side and long side directions of the display region 131 such that an image that conforms to the standard of full high vision broadcast can be displayed.

### <<Arithmetic Device>>

In the sixth step in the program described in Embodiment 3, the arithmetic device 110 of this embodiment generates the image data V containing the second image whose area is 2.7 times or more and 3.3 times or less that of the first image is generated so as to fit the display region of the display portion on the basis of data acquired in the third step, and displays the image data V (S6 in FIG. 5).

For example, the image data V containing an enlarged or downsized image is generated on the basis of the sensing data S containing data that shows the folded or unfolded state of the display portion 130, and the image data V is displayed on the display portion 130.

Specifically, in the state where the display portion 130 is folded, the image data V containing the first image is generated so as to occupy the first region 131(11) with a size that is approximately one third of the size of the display region 131 (see FIG. 7C). In the state where the display portion 130 is unfolded, the image data V containing the second image with a size that is 2.7 times or more and 3.3 times or less the size of the first image is generated and displayed (see FIG. 7A).

Thus, in the state where the display portion 130 is folded, the image data V can be displayed so as to occupy the first region 131(11). In the state where the display portion 130 is unfolded, the image data V can be displayed so as to occupy the entire display region 131.

### <<Other Components>>

The data processing device 100 includes the housing 101(1), the housing 101(2), and the housing 101(3). For example, resin, metal, or glass can be used for the housing (FIG. 7B).

The data processing device 100 includes the hinge 102(1) and the hinge 102(2). For example, resin or metal can be used for the hinge.

In the data processing device 100, one side of the housing 101(2) is connected to the housing 101(1) with the hinge 102(1), and the opposite side of the housing 101(2) is connected to the housing 101(3) with the hinge 102(2). With such a structure, the data processing device 100 can be varied in its form.

For example, a touch sensor may be provided so as to overlap with the third display region 131(13) which is provided substantially horizontally, and the second region 131(12) may be provided so as to be inclined at an angle with the use of the housing 101(1). In that case, a keyboard image used when a touch sensor is used as a software keyboard can be displayed on the third display region 131(13), and an input result or the like can be displayed on the second region 131(12) (see FIG. 8A).

For example, a side of the housing 101(3) to which the hinge 102(2) is not connected may be in contact with a side of the housing 101(1) to which the hinge 102(1) is not connected (see FIG. 8B).

The data processing device 100 includes the antenna 110A capable of transmitting and receiving, for example, modulated high-frequency waves.

The antenna 110A may be electrically connected to the communication portion 160 so that data supplied from the communication portion 160 can be supplied to an external device. The antenna 110A may supply the data supplied from the external device to the communication portion 160.

The antenna 110A may supply power supplied from an external wireless power feeding system to the battery 110B.

The data processing device 100 includes the battery 110B. For example, a lithium-ion battery can be used as the battery 110B.

The data processing device 100 includes the button 145(1). For example, a user of the data processing device 100 can supply an operating instruction to turn on or off the data processing device 100 by pressing the button 145(1).

This embodiment can be combined with any of the other embodiments in this specification as appropriate.

### Embodiment 5

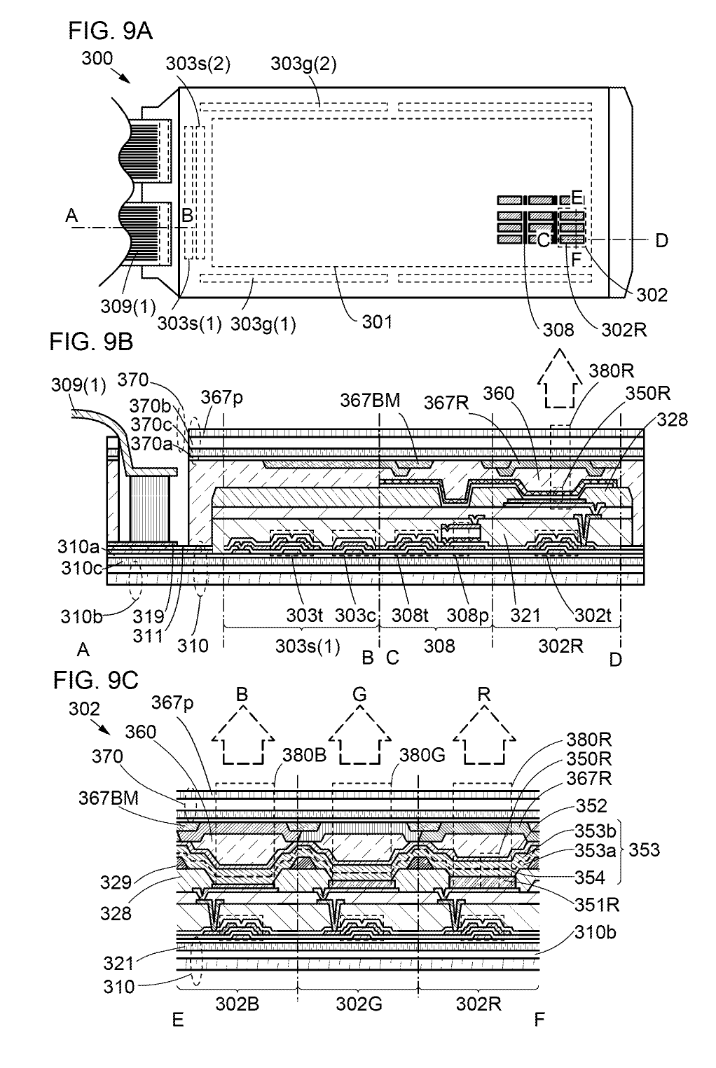

In this embodiment, the structure of a foldable touch panel that can be used in a display portion and an operating portion of the data processing device of one embodiment of the present invention will be described with reference to FIGS. 9A to 9C.

FIG. 9A is a top view illustrating the structure of a touch panel that can be used in the data processing device 100 of one embodiment of the present invention.

FIG. 9B is a cross-sectional view along A-B and C-D in FIG. 9A.

FIG. 9C is a cross-sectional view along E-F in FIG. 9A.

### <Top View>

A touch panel 300 described as an example in this embodiment includes a display portion 301 (see FIG. 9A).

The display portion 301 includes a plurality of pixels 302 and a plurality of imaging pixels 308. The imaging pixels 308 can sense a touch of a finger or the like on the display portion 301. Thus, a touch sensor can be formed using the imaging pixels 308.

Each of the pixels 302 includes a plurality of sub-pixels (e.g., a sub-pixel 302R). In addition, in the sub-pixels, light-emitting elements and pixel circuits that can supply electric power for driving the light-emitting elements are provided.

The pixel circuits are electrically connected to wirings through which selection signals are supplied and wirings through which image signals are supplied.

Furthermore, the touch panel 300 is provided with a scan line driver circuit 303g(1) that can supply selection signals to the pixels 302 and an image signal line driver circuit 303s(1) that can supply image signals to the pixels 302.

The imaging pixels 308 include photoelectric conversion elements and imaging pixel circuits that drive the photoelectric conversion elements.

The imaging pixel circuits are electrically connected to wirings through which control signals are supplied and wirings through which power supply potentials are supplied.

Examples of the control signals include a signal for selecting an imaging pixel circuit from which a recorded imaging signal is read, a signal for initializing an imaging pixel circuit, and a signal for determining the time it takes for an imaging pixel circuit to detect light.

The touch panel 300 is provided with an imaging pixel driver circuit 303g(2) that can supply control signals to the imaging pixels 308 and an imaging signal line driver circuit 303s(2) that reads out imaging signals.

### <Cross-Sectional View>

The touch panel 300 includes a substrate 310 and a counter substrate 370 that faces the substrate 310 (see FIG. 9B).

By using a flexible material as the substrate 310 and the counter substrate 370, the touch panel 300 can have flexibility.

Note that when the flexible touch panel 300 is changed in its form, stress is applied to a function element provided in the touch panel 300. A function element is preferably positioned in the center between the substrate 310 and the counter substrate 370 because a change in form of the function element can be prevented.

Furthermore, the substrate 310 is preferably formed using a material whose coefficient of linear expansion is substantially equal to that of the counter substrate 370. For example, the coefficient of linear expansion of the materials are preferably lower than or equal to 1×10⁻³/K, more preferably lower than or equal to 5×10⁻⁵/K, and still more preferably lower than or equal to 1×10⁻⁵/K.

For example, materials that contain polyester, polyolefin, polyamide (e.g., nylon or aramid), polyimide, polycarbonate, or a resin having an acrylic bond, a urethane bond, an epoxy bond, or a siloxane bond can be used for the substrate 310 and the counter substrate 370.

The substrate 310 is a stack including a substrate 310b having flexibility, a barrier film 310a that prevents diffusion of impurities to the light-emitting elements, and a resin layer 310c that attaches the barrier film 310a to the substrate 310b.

The counter substrate 370 is a stack including a substrate 370b having flexibility, a barrier film 370a that prevents diffusion of impurities to the light-emitting elements, and a resin layer 370c that attaches the barrier film 370a to the substrate 370b (see FIG. 9B).

A sealant 360 attaches the counter substrate 370 to the substrate 310. The sealant 360 also serving as an optical adhesive layer has a refractive index higher than that of air. The pixel circuits and the light-emitting elements (e.g., a first light-emitting element 350R) are provided between the substrate 310 and the counter substrate 370.

### <<Pixel Structure>>

Each of the pixels 302 includes a sub-pixel 302R, a sub-pixel 302G, and a sub-pixel 302B (see FIG. 9C). The sub-pixel 302R includes a light-emitting module 380R, the sub-pixel 302G includes a light-emitting module 380G, and the sub-pixel 302B includes a light-emitting module 380B.

For example, the sub-pixel 302R includes the first light-emitting element 350R and the pixel circuit that can supply electric power to the first light-emitting element 350R and includes a transistor 302t (see FIG. 9B). Furthermore, the light-emitting module 380R includes the first light-emitting element 350R and an optical element (e.g., a first coloring layer 367R).

The first light-emitting element 350R includes a first lower electrode 351R, an upper electrode 352, and a layer 353 containing a light-emitting organic compound between the first lower electrode 351R and the upper electrode 352 (see FIG. 9C).

The layer 353 containing a light-emitting organic compound includes a light-emitting unit 353a, a light-emitting unit 353b, and an intermediate layer 354 between the light-emitting units 353a and 353b.

The light-emitting module 380R includes the first coloring layer 367R on the counter substrate 370. The coloring layer transmits light with a particular wavelength and is, for example, a layer that selectively transmits red, green, or blue light. Alternatively, a region that transmits light emitted from the light-emitting element as it is may be provided.

The light-emitting module 380R, for example, includes the sealant 360 that is in contact with the first light-emitting element 350R and the first coloring layer 367R.

The first coloring layer 367R is positioned in a region overlapping with the first light-emitting element 350R. Accordingly, part of light emitted from the light-emitting element 350R passes through the sealant 360 that also serves as an optical adhesive layer and through the first coloring layer 367R and is emitted to the outside of the light-emitting module 380R as indicated by arrows in FIGS. 9B and 9C.

### <<Structure of Display Panel>>

The touch panel 300 includes a light-blocking layer 367BM on the counter substrate 370. The light-blocking layer 367BM is provided so as to surround the coloring layer (e.g., the first coloring layer 367R).

The touch panel 300 includes an anti-reflective layer 367p positioned in a region overlapping with the display portion 301. As the anti-reflective layer 367p, a circular polarizing plate can be used, for example.

The touch panel 300 includes an insulating film 321. The insulating film 321 covers the transistor 302t. Note that the insulating film 321 can be used as a layer for planarizing unevenness caused by the pixel circuits. An insulating film on which a layer that can prevent diffusion of impurities to the transistor 302t and the like is stacked can be used as the insulating film 321.

The touch panel 300 includes the light-emitting elements (e.g., the first light-emitting element 350R) over the insulating film 321.

The touch panel 300 includes, over the insulating film 321, a partition wall 328 that overlaps with an end portion of the first lower electrode 351R (see FIG. 9C). In addition, a spacer 329 that controls the distance between the substrate 310 and the counter substrate 370 is provided on the partition wall 328.

### <<Structure of Image Signal Line Driver Circuit>>

The image signal line driver circuit 303s(1) includes a transistor 303t and a capacitor 303c. Note that the driver circuit can be formed in the same process and over the same substrate as those of the pixel circuits.

### <<Structure of Imaging Pixel>>

The imaging pixels 308 each include a photoelectric conversion element 308p and an imaging pixel circuit for sensing light received by the photoelectric conversion element 308p. The imaging pixel circuit includes a transistor 308t.

For example, a PIN photodiode can be used as the photoelectric conversion element 308p.

### <<Other Components>>

The touch panel 300 includes a wiring 311 through which a signal is supplied. The wiring 311 is provided with a terminal 319. Note that an FPC 309(1) through which a signal such as an image signal or a synchronization signal is supplied is electrically connected to the terminal 319.

Note that a printed wiring board (PWB) may be attached to the FPC 309(1).

Transistors formed in the same process can be used as the transistor 302t, the transistor 303t, the transistor 308t, and the like.

Transistors of a bottom-gate type, a top-gate type, or the like can be used.

Any of various kinds of semiconductors can be used in the transistors. For example, an oxide semiconductor, single crystal silicon, polysilicon, amorphous silicon, or the like can be used.

This embodiment can be combined with any of the other embodiments in this specification as appropriate.

### Embodiment 6

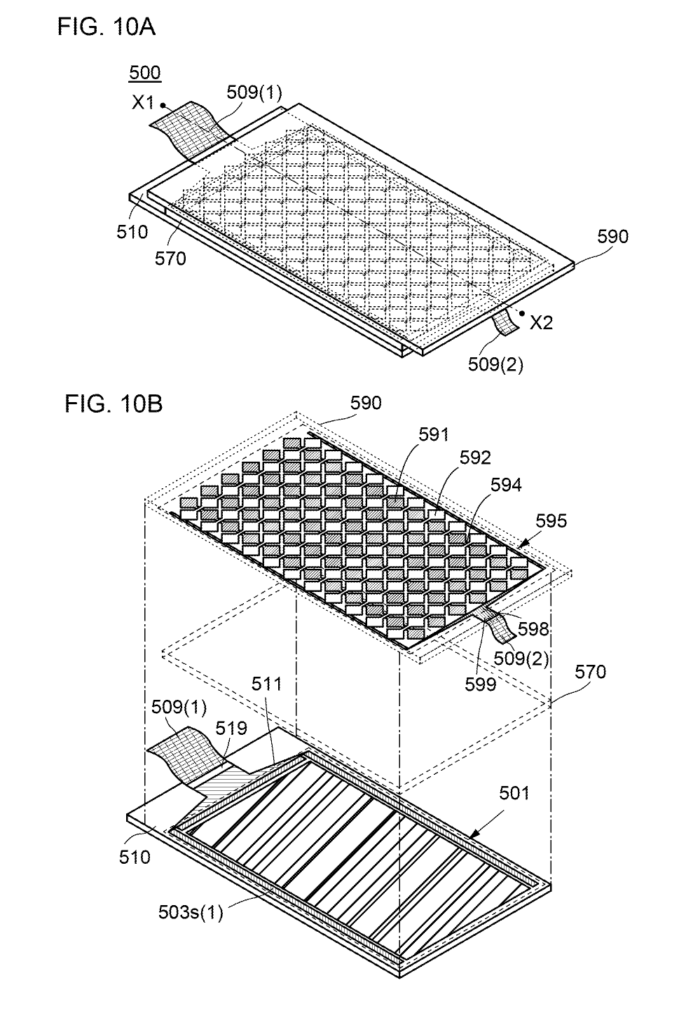

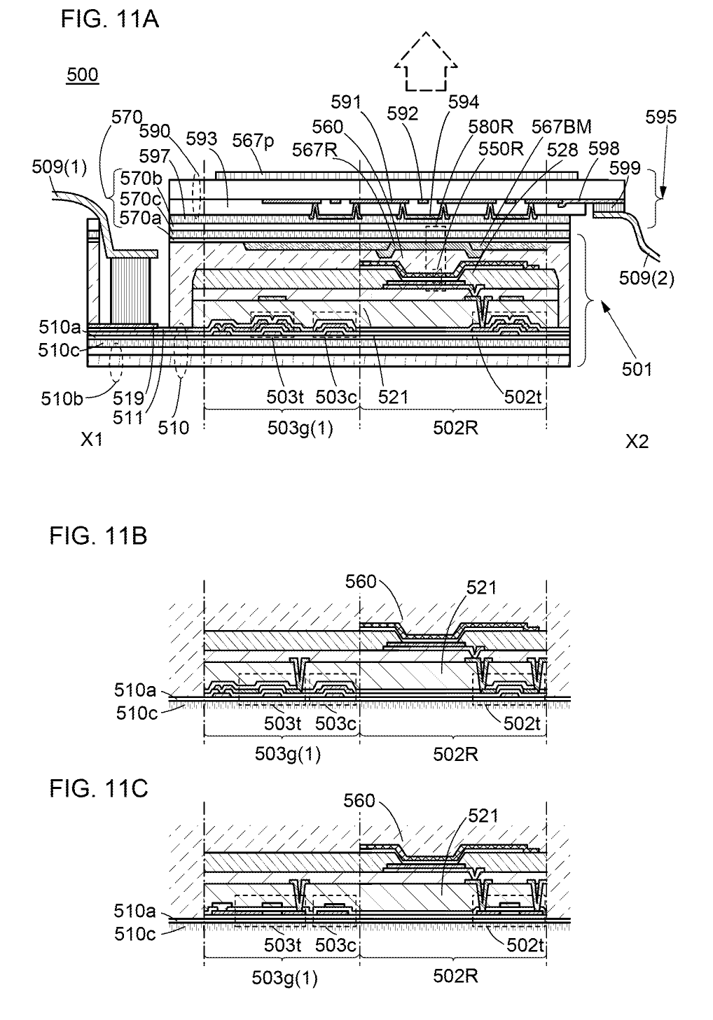

In this embodiment, the structures of foldable touch panels that can be used in the data processing device of one embodiment of the present invention will be described with reference to FIGS. 10A and 10B and FIGS. 11A to 11C.

FIG. 10A is a perspective view of a touch panel 500 described in this embodiment. Note that FIGS. 10A and 10B illustrate only main components for simplicity. FIG. 10B is a perspective view of the touch panel 500.

FIG. 11A is a cross-sectional view of the touch panel 500 along X1-X2 in FIG. 10A.

The touch panel 500 includes a display portion 501 and a touch sensor 595 (see FIG. 10B). Furthermore, the touch panel 500 includes a substrate 510, a substrate 570, and a substrate 590. Note that the substrate 510, the substrate 570, and the substrate 590 each have flexibility.

The display portion 501 includes the substrate 510, a plurality of pixels over the substrate 510, and a plurality of wirings 511 through which signals are supplied to the pixels. The plurality of wirings 511 is led to a peripheral portion of the substrate 510, and part of the plurality of wirings 511 forms a terminal 519. The terminal 519 is electrically connected to an FPC 509(1).

### <Touch Sensor>

The substrate 590 includes the touch sensor 595 and a plurality of wirings 598 electrically connected to the touch sensor 595. The plurality of wirings 598 is led to a peripheral portion of the substrate 590, and part of the plurality of wirings 598 forms a terminal. The terminal is electrically connected to an FPC 509(2). Note that in FIG. 10B, electrodes, wirings, and the like of the touch sensor 595 provided on the back side of the substrate 590 are indicated by solid lines for clarity.

As the touch sensor 595, a capacitive touch sensor can be used, for example. Examples of the capacitive touch sensor include a surface capacitive touch sensor and a projected capacitive touch sensor.

Examples of the projected capacitive touch sensor include a self capacitive touch sensor and a mutual capacitive touch sensor, which differ mainly in the driving method. The use of a mutual capacitive type is preferred because multiple points can be sensed simultaneously.

The case of using a projected capacitive touch sensor will be described below with reference to FIG. 10B.

Note that a variety of sensors that can sense the proximity or touch of a sensing target such as a finger, can be used.

The projected capacitive touch sensor 595 includes electrodes 591 and electrodes 592. The electrodes 591 are electrically connected to any of the plurality of wirings 598, and the electrodes 592 are electrically connected to any of the other wirings 598.

The electrodes 592 each have a shape of a plurality of quadrangles arranged in one direction with one corner of a quadrangle connected to one corner of another quadrangle as illustrated in FIGS. 10A and 10B.

The electrodes 591 each have a quadrangular shape and are arranged in the direction intersecting with the direction in which the electrodes 592 extend.

A wiring 594 electrically connects two electrodes 591 between which the electrode 592 is positioned. The intersecting area of the electrode 592 and the wiring 594 is preferably as small as possible. Such a structure allows a reduction in the area of a region where the electrodes are not provided, reducing unevenness in transmittance. As a result, unevenness in luminance of light transmitted through the touch sensor 595 can be reduced.

Note that the shapes of the electrodes 591 and the electrodes 592 are not limited to the above-mentioned shapes and can be any of a variety of shapes. For example, the plurality of electrodes 591 may be provided so that space between the electrodes 591 are reduced as much as possible, and a plurality of electrodes 592 may be provided with an insulating layer sandwiched between the electrodes 591 and the electrodes 592 and may be spaced apart from each other to form a region not overlapping with the electrodes 591. In that case, it is preferred that a dummy electrode that is electrically insulated from these electrodes be provided between two adjacent electrodes 592, whereby the area of a region having a different transmittance can be reduced.

The structure of the touch sensor 595 will be described with reference to FIG. 11A.

The touch sensor 595 includes the substrate 590, the electrodes 591 and the electrodes 592 provided in a staggered arrangement on the substrate 590, an insulating layer 593 covering the electrodes 591 and the electrodes 592, and the wiring 594 that electrically connects the adjacent electrodes 591 to each other.

A resin layer 597 attaches the substrate 590 to the substrate 570 such that the touch sensor 595 overlaps with the display portion 501.

The electrodes 591 and the electrodes 592 are formed using a light-transmitting conductive material. As a light-transmitting conductive material, a conductive oxide such as indium oxide, indium tin oxide, indium zinc oxide, zinc oxide, or zinc oxide to which gallium is added can be used. Note that a film including graphene may be used. The film including graphene can be formed, for example, by reducing a film including graphene oxide. As a reducing method, a method of applying heat or the like can be employed.

The electrodes 591 and the electrodes 592 may be formed by depositing a light-transmitting conductive material on the substrate 590 by a sputtering method and then removing an unnecessary portion by any of various patterning techniques such as photolithography.

Examples of a material for the insulating layer 593 include resins such as an acrylic resin and an epoxy resin, a resin having a siloxane bond, and inorganic insulating materials such as silicon oxide, silicon oxynitride, and aluminum oxide.

Furthermore, openings reaching the electrodes 591 are formed in the insulating layer 593, and the wiring 594 electrically connects the adjacent electrodes 591. A light-transmitting conductive material can be favorably used as the wiring 594 because the aperture ratio of the touch panel can be increased. Moreover, a material with higher conductivity than the conductivities of the electrodes 591 and 592 can be favorably used because electric resistance can be reduced.

One electrode 592 extends in one direction, and a plurality of electrodes 592 is provided in the form of stripes.

The wiring 594 intersects with the electrode 592.

Adjacent electrodes 591 are provided with one electrode 592 provided therebetween. The wiring 594 electrically connects the adjacent electrodes 591.

Note that the plurality of electrodes 591 is not necessarily arranged in the direction orthogonal to one electrode 592 and may be arranged to intersect with one electrode 592 at an angle of less than 90 degrees.

One wiring 598 is electrically connected to any of the electrodes 591 and 592. Part of the wiring 598 serves as a terminal. For the wiring 598, a metal material such as aluminum, gold, platinum, silver, nickel, titanium, tungsten, chromium, molybdenum, iron, cobalt, copper, or palladium or an alloy material containing any of these metal materials can be used.

Note that an insulating layer that covers the insulating layer 593 and the wiring 594 may be provided to protect the touch sensor 595.

Furthermore, a connection layer 599 electrically connects the wiring 598 to the FPC 509(2).

As the connection layer 599, any of various anisotropic conductive films (ACF), anisotropic conductive pastes (ACP), or the like can be used.

The resin layer 597 has a light-transmitting property. For example, a thermosetting resin or an ultraviolet curable resin can be used; specifically, a resin such as an acrylic resin, a urethane resin, an epoxy resin, or a resin having a siloxane bond can be used.

### <Display Portion>

The display portion 501 includes a plurality of pixels arranged in a matrix. Each of the pixels includes a display element and a pixel circuit for driving the display element.

In this embodiment, an example of using an organic electroluminescent element that emits white light as a display element will be described; however, the display element is not limited to such an element.

For example, organic electroluminescent elements that emit light of different colors may be included in sub-pixels so that the light of different colors can be emitted from the respective sub-pixels.

Other than organic electroluminescent elements, any of various display elements such as display elements (electronic ink) that perform display by an electrophoretic method, an electronic liquid powder (registered trademark) method, an electrowetting method, or the like; MEMS shutter display elements; optical interference type MEMS display elements; and liquid crystal elements can be used.

Furthermore, this embodiment can be used in a transmissive liquid crystal display, a transflective liquid crystal display, a reflective liquid crystal display, a direct-view liquid crystal display, or the like. In the case of a transflective liquid crystal display or a reflective liquid crystal display, some or all of pixel electrodes function as reflective electrodes. For example, some or all of pixel electrodes are formed to contain aluminum, silver, or the like. In such a case, a storage circuit such as an SRAM can be provided under the reflective electrodes, leading to lower power consumption. A structure suitable for employed display elements can be selected from among a variety of structures of pixel circuits.

In the display portion, an active matrix method in which an active element is included in a pixel or a passive matrix method in which an active element is not included in a pixel can be used.

In an active matrix method, as an active element (a non-linear element), not only a transistor but also various active elements (non-linear elements) can be used. For example, an MIM (metal insulator metal), a TFD (thin film diode), or the like can also be used. Since such an element has a small number of manufacturing steps, manufacturing cost can be reduced or yield can be improved. Alternatively, since the size of the element is small, the aperture ratio can be improved, so that power consumption can be reduced or higher luminance can be achieved.

As a method other than the active matrix method, the passive matrix method in which an active element (a non-linear element) is not used can also be used. Since an active element (a non-linear element) is not used, the number of manufacturing steps is small, so that manufacturing cost can be reduced or yield can be improved. Alternatively, since an active element (a non-linear element) is not used, the aperture ratio can be improved, so that power consumption can be reduced or higher luminance can be achieved, for example.

Flexible materials can be favorably used for the substrate 510 and the substrate 570.

Materials with which passage of impurities is inhibited can be favorably used for the substrate 510 and the substrate 570. For example, materials with a vapor permeability of lower than or equal to 10⁻⁵ g/m²·day, preferably lower than or equal to 10⁻⁶ g/m²·day can be favorably used.

The substrate 510 can be favorably formed using a material whose coefficient of linear expansion is substantially equal to that of the substrate 570. For example, the coefficient of linear expansion of the material is preferably lower than or equal to 1×10⁻³/K, more preferably lower than or equal to 5×10⁻⁵/K, and still more preferably lower than or equal to 1×10⁻⁵/K.

The substrate 510 is a stack in which a flexible substrate 510b, a barrier film 510a that prevents diffusion of impurities to light-emitting elements, and a resin layer 510c that attaches the barrier film 510a to the substrate 510b are stacked.

For example, materials that contain polyester, polyolefin, polyamide (e.g., nylon or aramid), polyimide, polycarbonate, or a resin having an acrylic bond, a urethane bond, an epoxy bond, or a siloxane bond can be used for the resin layer 510c.

The substrate 570 is a stack in which a flexible substrate 570b, a barrier film 570a that prevents diffusion of impurities to the light-emitting elements, and a resin layer 570c that attaches the barrier film 570a to the substrate 570b are stacked.

A sealant 560 attaches the substrate 570 to the substrate 510. The sealant 560 has a refractive index higher than that of air. In the case of extracting light to the sealant 560 side, the sealant 560 also serves as an optical adhesive layer. The pixel circuits and the light-emitting elements (e.g., a first light-emitting element 550R) are provided between the substrate 510 and the substrate 570.

### <<Pixel Structure>>

A pixel includes a sub-pixel 502R, and the sub-pixel 502R includes a light-emitting module 580R.

The sub-pixel 502R includes the first light-emitting element 550R and the pixel circuit that can supply electric power to the first light-emitting element 550R and includes a transistor 502t. Furthermore, the light-emitting module 580R includes the first light-emitting element 550R and an optical element (e.g., a coloring layer 567R).

The first light-emitting element 550R includes a lower electrode, an upper electrode, and a layer containing a light-emitting organic compound between the lower electrode and the upper electrode.

The light-emitting module 580R includes the first coloring layer 567R on the light extraction side. The coloring layer transmits light with a particular wavelength and is, for example, a layer that selectively transmits red, green, or blue light. Note that in another sub-pixel, a region that transmits light emitted from the light-emitting element as it is may be provided.

In the case where the sealant 560 is provided on the light extraction side, the sealant 560 is in contact with the first light-emitting element 550R and the first coloring layer 567R.

The first coloring layer 567R is positioned in a region overlapping with the first light-emitting element 550R. Accordingly, part of light emitted from the first light-emitting element 550R passes through the first coloring layer 567R and is emitted to the outside of the light-emitting module 580R as indicated by an arrow in FIG. 11A.

### <<Structure of Display Portion>>

The display portion 501 includes a light-blocking layer 567BM on the light extraction side. The light-blocking layer 567BM is provided so as to surround the coloring layer (e.g., the first coloring layer 567R).

The display portion 501 includes an anti-reflective layer 567p positioned in a region overlapping with pixels. As the anti-reflective layer 567p, a circular polarizing plate can be used, for example.

The display portion 501 includes an insulating film 521. The insulating film 521 covers the transistor 502t. Note that the insulating film 521 can be used as a layer for planarizing unevenness due to the pixel circuit. A layered film including a layer that can prevent diffusion of impurities can be used as the insulating film 521. This can prevent the reliability of the transistor 502t or the like from being lowered by diffusion of impurities.

The display portion 501 includes the light-emitting elements (e.g., the first light-emitting element 550R) over the insulating film 521.

The display portion 501 includes, over the insulating film 521, a partition wall 528 that overlaps with an end portion of the lower electrode. In addition, a spacer that controls the distance between the substrate 510 and the substrate 570 is provided on the partition wall 528.

### <<Structural Example of Scan Line Driver Circuit>>

A scan line driver circuit 503g(1) includes a transistor 503t and a capacitor 503c. Note that the driver circuit can be formed in the same process and over the same substrate as those of the pixel circuits.

### <<Other Components>>

The display portion 501 includes the wirings 511 through which signals are supplied. The wirings 511 are provided with the terminal 519. Note that the FPC 509(1) through which a signal such as an image signal or a synchronization signal can be supplied is electrically connected to the terminal 519.

Note that a printed wiring board (PWB) may be attached to the FPC 509(1).

The display portion 501 includes wirings such as scan lines, signal lines, and power supply lines. Any of various conductive films can be used for the wirings.

Specifically, a metal element selected from aluminum, chromium, copper, tantalum, titanium, molybdenum, tungsten, nickel, yttrium, zirconium, silver, and manganese; an alloy containing any of the above-described metal elements; an alloy containing any of the above-described metal elements in combination; or the like can be used. In particular, one or more elements selected from aluminum, chromium, copper, tantalum, titanium, molybdenum, and tungsten are preferably contained. In particular, an alloy of copper and manganese is suitably used in microfabrication with the use of a wet etching method.

Specifically, a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, a three-layer structure in which a titanium film, an aluminum film, and a titanium film are stacked in this order, or the like can be used.

Specifically, a layered film in which a film that contains an element selected from titanium, tantalum, tungsten, molybdenum, chromium, neodymium, and scandium is stacked over an aluminum-containing film may be used. Alternatively, a layered film in which a film that contains more than one elements selected from titanium, tantalum, tungsten, molybdenum, chromium, neodymium, and scandium is stacked over an aluminum-containing film may be used.

Alternatively, a light-transmitting conductive material containing indium oxide, tin oxide, or zinc oxide may be used.

### Modification Example 1 of Display Portion

Any of various kinds of transistors can be used in the display portion 501.

A structure of the case of using bottom-gate transistors in the display portion 501 is illustrated in FIGS. 11A and 11B.

For example, a semiconductor layer containing an oxide semiconductor, amorphous silicon, or the like can be used in the transistor 502t and the transistor 503t illustrated in FIG. 11A.

For example, a film represented by an In-M-Zn oxide that contains at least indium (In), zinc (Zn), and M (M is a metal such as Al, Ga, Ge, Y, Zr, Sn, La, Ce, or Hf) is preferably included. Alternatively, both In and Zn are preferably contained.

As a stabilizer, gallium (Ga), tin (Sn), hafnium (Hf), aluminum (Al), zirconium (Zr), and the like can be given. As another stabilizer, lanthanoids such as lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu) can be given.

As an oxide semiconductor included in an oxide semiconductor film, any of the followings can be used, for example: an In—Ga—Zn-based oxide, an In—Al—Zn-based oxide, an In—Sn—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, an In—Lu—Zn-based oxide, an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, an In—Hf—Al—Zn-based oxide, and an In—Ga-based oxide.

Note that here, for example, an “In—Ga—Zn-based oxide” means an oxide containing In, Ga, and Zn as its main components and there is no limitation on the ratio of In:Ga:Zn. The In—Ga—Zn-based oxide may contain another metal element in addition to In, Ga, and Zn.

For example, a semiconductor layer containing polycrystalline silicon that is obtained by crystallization process such as laser annealing can be used in the transistor 502t and the transistor 503t illustrated in FIG. 11B.

A structure of the case of using top-gate transistors in the display portion 501 is illustrated in FIG. 11C.

For example, a semiconductor layer containing polycrystalline silicon, a single crystal silicon film that is transferred from a single crystal silicon substrate, or the like can be used in the transistor 502t and the transistor 503t illustrated in FIG. 11C.

This embodiment can be combined with any of the other embodiments in this specification as appropriate.

### Embodiment 7

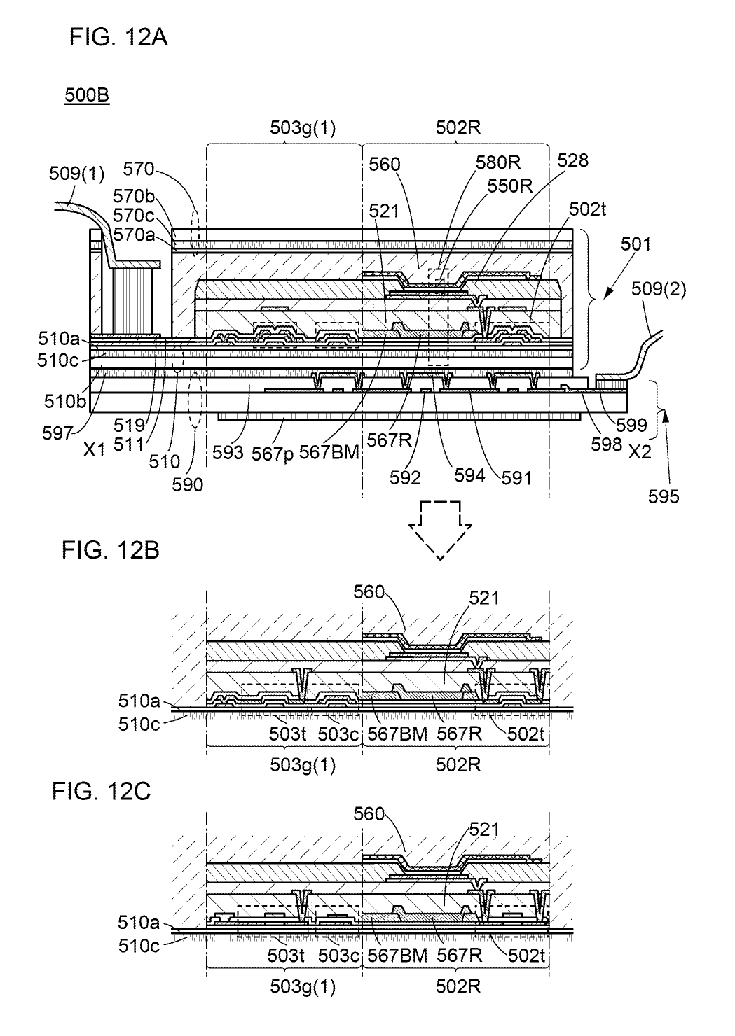

In this embodiment, structures of a foldable touch panel that can be used in a data processing device of one embodiment of the present invention will be described with reference to FIGS. 12A to 12C.

FIGS. 12A to 12C are cross-sectional views of a touch panel 500B.

The touch panel 500B described in this embodiment is different from the touch panel 500 described in Embodiment 6 in that the display portion 501 displays received image data to the side where the transistors are provided and that the touch sensor is provided on the substrate 510 side of the display portion. Different structures will be described in detail below, and the above description is referred to for the other similar structures.

### <Display Portion>

The display portion 501 includes a plurality of pixels arranged in a matrix. Each of the pixels includes a display element and a pixel circuit for driving the display element.

### <<Pixel Structure>>

A pixel includes a sub-pixel 502R, and the sub-pixel 502R includes a light-emitting module 580R.

The sub-pixel 502R includes the first light-emitting element 550R and the pixel circuit that can supply electric power to the first light-emitting element 550R and includes a transistor 502t.

The light-emitting module 580R includes the first light-emitting element 550R and an optical element (e.g., the first coloring layer 567R).

The first light-emitting element 550R includes a lower electrode, an upper electrode, and a layer containing a light-emitting organic compound between the lower electrode and the upper electrode.

The light-emitting module 580R includes the first coloring layer 567R on the light extraction side. The coloring layer transmits light with a particular wavelength and is, for example, a layer that selectively transmits red, green, or blue light. Note that in another sub-pixel, a region that transmits light emitted from the light-emitting element as it is may be provided.

The first coloring layer 567R is positioned in a region overlapping with the first light-emitting element 550R. The first light-emitting element 550R illustrated in FIG. 12A emits light to the side where the transistor 502t is provided. Accordingly, part of light emitted from the first light-emitting element 550R passes through the first coloring layer 567R and is emitted to the outside of the light-emitting module 580R as indicated by an arrow in FIG. 12A.

### <<Structure of Display Portion>>

The display portion 501 includes a light-blocking layer 567BM on the light extraction side. The light-blocking layer 567BM is provided so as to surround the coloring layer (e.g., the first coloring layer 567R).

The display portion 501 includes an insulating film 521. The insulating film 521 covers the transistor 502t. Note that the insulating film 521 can be used as a layer for planarizing unevenness due to the pixel circuit. A layered film including a layer that can prevent diffusion of impurities can be used as the insulating film 521. This can prevent the decrease of the reliability of the transistor 502t or the like due to diffusion of impurities from the first coloring layer 567R.

### <Touch Sensor>

The touch sensor 595 is provided on the substrate 510 side of the display portion 501 (see FIG. 12A).

The adhesive layer 597 is provided between the substrate 510 and the substrate 590 and bonds the touch sensor 595 to the display portion 501.

### Modification Example 1 of Display Portion

Any of various kinds of transistors can be used in the display portion 501.

FIGS. 12A and 12B illustrate a structure of the case where bottom-gate transistors are used in the display portion 501.

For example, a semiconductor layer containing an oxide semiconductor, amorphous silicon, or the like can be used in the transistor 502t and the transistor 503t illustrated in FIG. 12A. In the transistors, a channel formation region may be sandwiched between upper and lower gate electrodes, in which case variations in characteristics of the transistors can be prevented and thus the reliability can be increased.

For example, a semiconductor layer containing polycrystalline silicon or the like can be used in the transistor 502t and the transistor 503t illustrated in FIG. 12B.

FIG. 12C illustrates a structure of the case where top-gate transistors are used in the display portion 501.

For example, a semiconductor layer containing polycrystalline silicon, a transferred single crystal silicon film, or the like can be used in the transistor 502t and the transistor 503t illustrated in FIG. 12C.

This embodiment can be combined with any of the other embodiments in this specification as appropriate.

### Embodiment 8

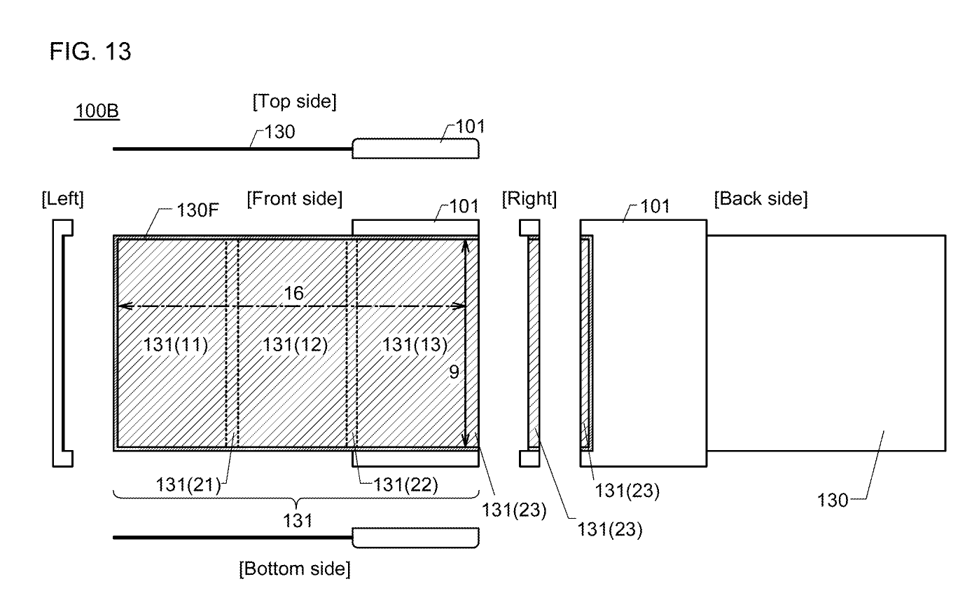

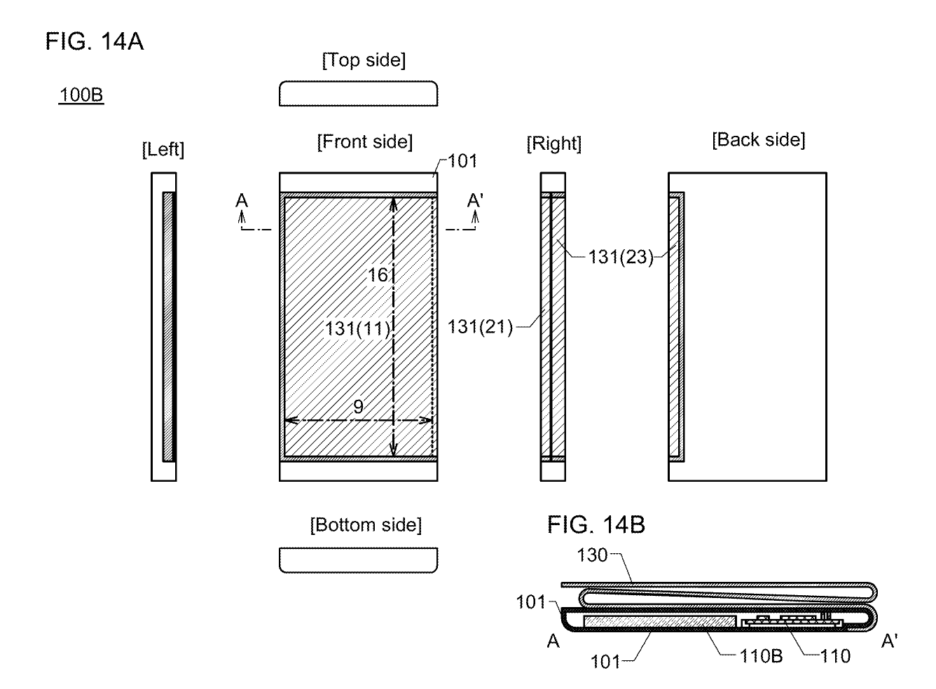

In this embodiment, the structures of data processing devices of embodiments of the present invention will be described with reference to FIG. 13 and FIGS. 14A and 14B.

FIG. 13 is a hexahedral view illustrating an unfolded display portion of the data processing device of one embodiment of the present invention.

FIGS. 14A and 14B illustrate a folded display portion of the data processing device of one embodiment of the present invention. FIG. 14A is a hexahedral view, and FIG. 14B is a cross-sectional view along A-A′.

### Structural Example of Data Processing Device

A data processing device 100B of one embodiment of the present invention includes the display portion 130 where the first region 131(11), the first bendable region 131(21), the second region 131(12), the second bendable region 131(22), the third region 131(13), and a third bendable region 131(23) are arranged in stripes in this order. The display portion 130 can be folded and unfolded along a first fold line formed in the first bendable region 131(21) and a second fold line formed in the second bendable region 131(22) (see FIG. 13 and FIGS. 14A and 14B).

The ratio of the length of a short side of the first region 131(11) to the length of a long side thereof is 0.9 times or more and 1.1 times or less the ratio of the length of a short side of the display region 131 to the length of a long side thereof. The ratio of the length of the short side of the first region to the length of the long side thereof is approximately 9:16.

The data processing device 100B described in this embodiment includes the display portion 130 where the first region 131(11), the first bendable region 131(21), and the second bendable region 131(12) are arranged in stripes in this order. The display portion 130 can be folded along the first bendable region 131(21) such that the ratio of the length of the short side of the first region 131(11) to the length of the long side thereof ( 9/16) is 0.9 times or more and 1.1 times or less the ratio of the length of the short side of the display region 131 to the length of the long side thereof ( 9/16).

With such a structure, an image having approximately the same ratio of the vertical length to the horizontal length as an image displayed on the first region 131(11) of the display region 131 in a folded state can be displayed on the display region 131 in an unfolded state. Thus, the novel display panel can be highly convenient or reliable.

The data processing device 100B further includes the arithmetic device 110, the battery 110B, and the housing 101 (see FIG. 14B). The arithmetic device 110 is supplied with a power supply potential and supplies image data. The battery 110B supplies a power supply potential. The arithmetic device 110 and the battery 110B are provided in the housing 101.

The display portion 130 is supplied with image data and a power supply potential and displays the image data.

The third bendable region 131(23) is provided so as to be bendable along a side surface of the housing 101, and image data can be displayed on a side surface and a back surface of the data processing device 100B (see FIG. 14A).

The display portion 130 may have a frame 130F outside the display region 131. The frame 130F is not necessarily provided with a display element and may be supplied with a blank image signal.

A touch sensor can be provided so as to overlap with the display portion 130. The display portion with which the touch sensor overlaps can be called a touch panel.

The touch panel can supply positional data, and the arithmetic device is supplied with the positional data.

This embodiment can be combined with any of the other embodiments in this specification as appropriate.

Note that what is described (or part thereof) in one embodiment can be applied to, combined with, or replaced with different contents in the embodiment and/or what is described (or part thereof) in another embodiment or other embodiments.

Note that in each embodiment, what is described in the embodiment is contents described with reference to a variety of diagrams or contents described with text described in this specification.

Note that by combining a diagram (or may be part of the diagram) illustrated in one embodiment with another part of the diagram, a different diagram (or may be part of the different diagram) illustrated in the embodiment, and/or a diagram (or may be part of the diagram) illustrated in another embodiment or other embodiments, much more diagrams can be formed.

Note that contents that are not specified in any drawing or text in the specification can be excluded from one embodiment of the invention. Alternatively, when the range of a value that is defined by the maximum and minimum values is described, part of the range is appropriately narrowed and part of the range is removed, whereby one embodiment of the invention can be constituted excluding part of the range can be constructed. In this manner, it is possible to specify the technical scope of one embodiment of the present invention so that a conventional technology is excluded, for example.

As a specific example, a diagram of a circuit including first to fifth transistors is illustrated. In that case, it can be specified that the circuit does not include a sixth transistor in the invention. It can be specified that the circuit does not include a capacitor in the invention. It can be specified that the circuit does not include a sixth transistor with a particular connection structure in the invention. It can be specified that the circuit does not include a capacitor with a particular connection structure in the invention. For example, it can be specified that a sixth transistor whose gate is connected to a gate of the third transistor is not included in the invention. For example, it can be specified that a capacitor whose first electrode is connected to the gate of the third transistor is not included in the invention.

As another specific example, the description of a value, “a voltage is preferably higher than or equal to 3 V and lower than or equal to 10 V” is given. In that case, for example, it can be specified that the case where the voltage is higher than or equal to −2 V and lower than or equal to 1 V is excluded from one embodiment of the invention. For example, it can be specified that the case where the voltage is higher than or equal to 13 V is excluded from one embodiment of the invention. Note that, for example, it can be specified that the voltage is higher than or equal to 5 V and lower than or equal to 8 V in the invention. For example, it can be specified that the voltage is approximately 9 V in the invention. For example, it can be specified that the voltage is higher than or equal to 3 V and lower than or equal to 10 V but is not 9 V in the invention. Note that even when the description “a value is preferably in a certain range” or “a value preferably satisfies a certain condition” is given, the value is not limited to the description. In other words, a description of a value that includes a term “preferable”, “preferably”, or the like does not necessarily limit the value.

As another specific example, the description “a voltage is preferred to be 10 V” is given. In that case, for example, it can be specified that the case where the voltage is higher than or equal to −2 V and lower than or equal to 1 V is excluded from one embodiment of the invention. For example, it can be specified that the case where the voltage is higher than or equal to 13 V is excluded from one embodiment of the invention.

As another specific example, the description “a film is an insulating film” is given to describe a property of a material. In that case, for example, it can be specified that the case where the insulating film is an organic insulating film is excluded from one embodiment of the invention. For example, it can be specified that the case where the insulating film is an inorganic insulating film is excluded from one embodiment of the invention. For example, it can be specified that the case where the insulating film is a conductive film is excluded from one embodiment of the invention. For example, it can be specified that the case where the insulating film is a semiconductor film is excluded from one embodiment of the invention.

As another specific example, the description of a stacked structure, “a film is provided between an A film and a B film” is given. In that case, for example, it can be specified that the case where the film is a layered film of four or more layers is excluded from the invention. For example, it can be specified that the case where a conductive film is provided between the A film and the film is excluded from the invention.

Note that various people can implement one embodiment of the invention described in this specification and the like. However, different people may be involved in the implementation of the embodiment of the invention. For example, in the case of a transmission/reception system, the following case is possible: Company A manufactures and sells transmitting devices, and Company B manufactures and sells receiving devices. As another example, in the case of a light-emitting device including a transistor and a light-emitting element, the following case is possible: Company A manufactures and sells semiconductor devices including transistors, and Company B purchases the semiconductor devices, provides light-emitting elements for the semiconductor devices, and completes light-emitting devices.

In such a case, one embodiment of the invention can be constituted so that a patent infringement can be claimed against each of Company A and Company B. In other words, one embodiment of the invention can be constituted so that only Company A implements the embodiment, and another embodiment of the invention can be constituted so that only Company B implements the embodiment. One embodiment of the invention with which a patent infringement suit can be filed against Company A or Company B is clear and can be regarded as being disclosed in this specification or the like. For example, in the case of a transmission/reception system, even when this specification or the like does not include a description of the case where a transmitting device is used alone or the case where a receiving device is used alone, one embodiment of the invention can be constituted by only the transmitting device and another embodiment of the invention can be constituted by only the receiving device. Those embodiments of the invention are clear and can be regarded as being disclosed in this specification or the like. Another example is as follows: in the case of a light-emitting device including a transistor and a light-emitting element, even when this specification or the like does not include a description of the case where a semiconductor device including the transistor is used alone or the case where a light-emitting device including the light-emitting element is used alone, one embodiment of the invention can be constituted by only the semiconductor device including the transistor and another embodiment of the invention can be constituted by only the light-emitting device including the light-emitting element. Those embodiments of the invention are clear and can be regarded as being disclosed in this specification or the like.

Note that in this specification and the like, it may be possible for those skilled in the art to constitute one embodiment of the invention even when portions to which all the terminals of an active element (e.g., a transistor or a diode), a passive element (e.g., a capacitor or a resistor), and the like are connected are not specified. In other words, one embodiment of the invention is clear even when connection portions are not specified. Further, in the case where a connection portion is disclosed in this specification and the like, it can be determined that one embodiment of the invention in which a connection portion is not specified is disclosed in this specification and the like, in some cases. In particular, in the case where the number of portions to which the terminal is connected may be more than one, it is not necessary to specify the portions to which the terminal is connected. Therefore, it may be possible to constitute one embodiment of the invention by specifying only portions to which some of terminals of an active element (e.g., a transistor or a diode), a passive element (e.g., a capacitor or a resistor), and the like are connected.

Note that in this specification and the like, it may be possible for those skilled in the art to specify the invention when at least the connection portion of a circuit is specified. Alternatively, it may be possible for those skilled in the art to specify the invention when at least a function of a circuit is specified. In other words, when a function of a circuit is specified, one embodiment of the present invention is clear. Moreover, it can be determined that one embodiment of the present invention whose function is specified is disclosed in this specification and the like. Therefore, when a connection portion of a circuit is specified, the circuit is disclosed as one embodiment of the invention even when a function is not specified, and one embodiment of the invention can be constituted. Alternatively, when a function of a circuit is specified, the circuit is disclosed as one embodiment of the invention even when a connection portion is not specified, and one embodiment of the invention can be constituted.

Note that in this specification and the like, part of a diagram or text described in one embodiment can be taken out to constitute one embodiment of the invention. Thus, in the case where a diagram or text related to a certain portion is described, the contents taken out from part of the diagram or the text are also disclosed as one embodiment of the invention, and one embodiment of the invention can be constituted. The embodiment of the present invention is clear. Therefore, for example, in a diagram or text in which one or more active elements (e.g., transistors or diodes), wirings, passive elements (e.g., capacitors or resistors), conductive layers, insulating layers, semiconductor layers, organic materials, inorganic materials, components, devices, operating methods, manufacturing methods, or the like are described, part of the diagram or the text is taken out, and one embodiment of the invention can be constituted. For example, from a circuit diagram in which N circuit elements (e.g., transistors or capacitors; N is an integer) are provided, it is possible to take out M circuit elements (e.g., transistors or capacitors; M is an integer, where M<N) and constitute one embodiment of the invention. For another example, it is possible to take out M layers (M is an integer, where M<N) from a cross-sectional view in which N layers (N is an integer) are provided and constitute one embodiment of the invention. For another example, it is possible to take out M elements (M is an integer, where M<N) from a flow chart in which N elements (N is an integer) are provided and constitute one embodiment of the invention. For another example, it is possible to take out some given elements from a sentence “A includes B, C, D, E, or F” and constitute one embodiment of the invention, for example, “A includes B and E”, “A includes E and F”, “A includes C, E, and F”, or “A includes B, C, D, and E”.

Note that in the case where at least one specific example is described in a diagram or text described in one embodiment in this specification and the like, it will be readily appreciated by those skilled in the art that a broader concept of the specific example can be derived. Therefore, in the diagram or the text described in one embodiment, in the case where at least one specific example is described, a broader concept of the specific example is disclosed as one embodiment of the invention, and one embodiment of the invention can be constituted. The embodiment of the present invention is clear.

Note that in this specification and the like, what is illustrated in at least a diagram (which may be part of the diagram) is disclosed as one embodiment of the invention, and one embodiment of the invention can be constituted. Therefore, when certain contents are described in a diagram, the contents are disclosed as one embodiment of the invention even when the contents are not described with text, and one embodiment of the invention can be constituted. In a similar manner, part of a diagram, which is taken out from the diagram, is disclosed as one embodiment of the invention, and one embodiment of the invention can be constituted. The embodiment of the present invention is clear.

### EXPLANATION OF REFERENCE

100: data processing device, 100B: data processing device, 101: housing, 102: hinge, 110: arithmetic device, 110A: antenna, 110B: battery, 111: arithmetic portion, 112: storage portion, 114: transmission path, 115: input/output interface, 120: input/output device, 130: display portion, 130F: frame, 130P: display panel, 130PB: display panel, 131: display region, 131(11): first region, 131(12): second region, 131(13): third region, 131(21): first bendable region, 131(22): second bendable region, 131(23): third bendable region, 133G(L): first scan line driver circuit, 133G(R): second scan line driver circuit, 133S(L): first signal line driver circuit, 133S(R): second signal line driver circuit, 139: flexible printed circuit FPC, 140: positional data input portion, 145: input/output portion, 145(1): button, 150(1): sensing circuit, 150(2): sensing circuit, 150(3): sensing circuit, 150: sensor portion, 160: communication portion, 300: touch panel, 301: display portion, 302: pixel, 302B: sub-pixel, 302G: sub-pixel, 302R: sub-pixel, 302t: transistor, 303c: capacitor, 303g(1): scan line driver circuit, 303g(2): imaging pixel driver circuit, 303s(1): image signal line driver circuit, 303s(2): imaging signal line driver circuit, 303t: transistor, 308: imaging pixel, 308p: photoelectric conversion element, 308t: transistor, 309: FPC, 310: substrate, 310a: barrier film, 310b: substrate, 310c: resin layer, 311: wiring, 319: terminal, 321: insulating film, 328: partition wall, 329: spacer, 350R: light-emitting element, 351R: lower electrode, 352: upper electrode, 353: layer, 353a: light-emitting unit, 353b: light-emitting unit, 354: intermediate layer, 360: sealant, 367BM: light-blocking layer, 367p: anti-reflective layer, 367R: coloring layer, 370: counter substrate, 370a: barrier film, 370b: substrate, 370c: resin layer, 380B: light-emitting module, 380G: light-emitting module, 380R: light-emitting module, 500: touch panel, 500B: touch panel, 501: display portion, 502R: sub-pixel, 502t: transistor, 503c: capacitor, 503g: scan line driver circuit, 503t: transistor, 509: FPC, 510: substrate, 510a: barrier film, 510b: substrate, 510c: resin layer, 511: wiring, 519: terminal, 521: insulating film, 528: partition wall, 550R: light-emitting element, 560: sealant, 567BM: light-blocking layer, 567p: anti-reflective layer, 567R: coloring layer, 570: substrate, 570a: barrier film, 570b: substrate, 570c: resin layer, 580R: light-emitting module, 590: substrate, 591: electrode, 592: electrode, 593: insulating layer, 594: wiring, 595: touch sensor, 597: resin layer, 598: wiring, and 599: connection layer

This application is based on Japanese Patent Application serial No. 2014-024974 filed with the Japan Patent Office on Feb. 13, 2014, the entire contents of which are hereby incorporated by reference.

1. A display panel comprising:
a display region including a first region and a second region with a bendable region interposed between the first region and the second region,
wherein the display region can be folded and unfolded along a fold line formed in the bendable region, and
wherein a ratio of a length of a short side of the first region to a length of a long side thereof is 0.9 times or more and 1.1 times or less a ratio of a length of a short side of the display region to a length of a long side thereof.

2. The display panel according to claim 1, wherein the ratio of the length of the short side of the first region to the length of the long side thereof is approximately 9:16.

3. The display panel according to claim 1, wherein the first region and the second region are provided in stripes.

4. A display panel comprising:
a display region including a first region, a second region and a third region with a first bendable region interposed between the first region and the second region, and with a second bendable region interposed between the second region and the third region,
wherein the display region can be folded and unfolded along a first fold line formed in the first bendable region and a second fold line formed in the second bendable region,
wherein a ratio of a length of a short side of the first region to a length of a long side thereof is 0.9 times or more and 1.1 times or less a ratio of a length of a short side of the display region to a length of a long side thereof, and
wherein the ratio of the length of the short side of the first region to the length of the long side thereof is approximately 9:16.

5. The display panel according to claim 4, wherein the first region, the second region and the third region are provided in stripes.

6. A data processing device comprising:
an input/output device configured to be supplied with image data and to supply sensing data; and
an arithmetic device configured to supply the image data and to be supplied with the sensing data,
wherein the input/output device includes a display portion configured to be supplied with the image data and a sensor portion configured to supply the sensing data,
wherein the display portion contains a display region including a first region, a second region and a third region with a first bendable region interposed between the first region and the second region and with a second bendable region interposed between the second region and the third region,
wherein a ratio of a length of a short side of the first region to a length of a long side thereof is 0.9 times or more and 1.1 times or less a ratio of a length of a short side of the display region to a length of a long side thereof,
wherein the ratio of the length of the short side of the first region to the length of the long side thereof is approximately 9:16,
wherein the display portion can be folded and unfolded along a first fold line formed in the first bendable region and a second fold line formed in the second bendable region,
wherein the sensor portion determines whether the display portion is folded or unfolded, and supplies sensing data which contains data showing a determined state,
wherein the arithmetic device supplies image data containing a first image which fits the first region in the case where the sensing data shows a folded state, and supplies image data containing a second image which is approximately similar to the first image and fits the display region of the display portion in the case where the sensing data shows an unfolded state, and
wherein an area of the second image is 2.7 times or more and 3.3 times or less that of the first image.

7. The data processing device according to claim 6,
wherein the arithmetic device includes an arithmetic portion and a storage portion which stores a program to be executed by the arithmetic portion,
wherein the program includes:
a first step of acquiring initial data containing status data;
a second step of allowing interrupt processing;
a third step of acquiring predetermined data;
a fourth step of selecting a fifth step when the status data shows a first status or a sixth step when the status data shows a second status;
the fifth step of generating image data containing the first image such that it fits the first region on the basis of the data acquired in the third step and displaying the image data;
the sixth step of generating image data containing the second image such that it fits the display region of a display portion on the basis of the data acquired in the third step and displaying the image data;
a seventh step of selecting an eighth step when a termination instruction is supplied in the interrupt processing or the third step when no termination instruction is supplied in the interrupt processing; and
the eighth step of terminating the program, and
wherein the interrupt processing includes:
a ninth step of acquiring sensing data containing data which shows the folded or unfolded state of the display portion;
a tenth step of determining candidate data on the basis of the sensing data;
an eleventh step of selecting a twelfth step when the candidate data differs from the status data or the ninth step when the candidate data is the same as the status data;
the twelfth step of updating the status data to the candidate data; and
a thirteenth step of returning from the interrupt processing.

8. The data processing device according to claim 6, wherein the first region, the second region and the third region are provided in stripes.

9. A data processing device comprising:
an input/output device configured to be supplied with image data and to supply sensing data; and
an arithmetic device configured to supply the image data and to be supplied with the sensing data,
wherein the input/output device includes a display portion configured to be supplied with the image data and a sensor portion configured to supply the sensing data,
wherein the display portion contains a display region including a first region and a second region with a bendable region interposed between the first region and the second region,
wherein the display portion can be folded along a fold line formed in the bendable region,
wherein the sensor portion determines whether the display portion is folded or unfolded, and supplies sensing data which contains data showing a determined state,
wherein the arithmetic device supplies image data containing a first image which fits the first region in the case where the sensing data shows a folded state, and supplies image data containing a second image which is approximately similar to the first image and fits the display region of the display portion in the case where the sensing data shows an unfolded state, and
wherein a ratio of a vertical length of the second image to a horizontal length thereof is 0.9 times or more and 1.1 times or less a ratio of a vertical length of the first image to a horizontal length thereof.

10. The data processing device according to claim 9, wherein the second image is larger than the first image.

11. The data processing device according to claim 9,
wherein one of the vertical length and the horizontal length of the first image is 0.9 times or more the length of a short side or a long side of the first region, or
wherein one of the vertical length and the horizontal length of the second image is 0.9 times or more the length of a short side or a long side of the display region.

12. The data processing device according to claim 9,
wherein the image data contains a third image displayed outside a region where the first image or the second image is displayed.

13. The data processing device according to claim 9,
wherein the sensor portion determines a position of the display portion and supplies sensing data containing data which shows the determined position, and
wherein the arithmetic device determines a direction of the first image or the second image on the basis of the sensing data, and generates image data containing the first image or the second image located in the determined direction.

14. The data processing device according to claim 9,
wherein the arithmetic device includes an arithmetic portion and a storage portion which stores a program to be executed by the arithmetic portion,
wherein the program includes:
a first step of acquiring initial data containing status data;
a second step of allowing interrupt processing;
a third step of acquiring predetermined data;
a fourth step of selecting a fifth step when the status data shows a first status or a sixth step when the status data shows a second status;
the fifth step of generating image data containing the first image such that it fits the first region on the basis of the data acquired in the third step and displaying the image data;
the sixth step of generating image data containing the second image such that it fits the display region of a display portion on the basis of the data acquired in the third step and displaying the image data;
a seventh step of selecting an eighth step when a termination instruction is supplied in the interrupt processing or the third step when no termination instruction is supplied in the interrupt processing; and
the eighth step of terminating the program, and
wherein the interrupt processing includes:
a ninth step of acquiring sensing data containing data which shows the folded or unfolded state of the display portion;
a tenth step of determining candidate data on the basis of the sensing data;
an eleventh step of selecting a twelfth step when the candidate data differs from the status data or the ninth step when the candidate data is the same as the status data;
the twelfth step of updating the status data to the candidate data; and
a thirteenth step of returning from the interrupt processing.

15. The data processing device according to claim 9, wherein the first region and the second region are provided in stripes.
